(19) United States
(12) Patent Application Publication
(10) Pub. No.: US 2025/0014946 A1
(43) Pub. Date: Jan. 9, 2025

(54) Cut Metal Gate Refill With Buffer Layer

(71) Applicant: Taiwan Semiconductor Manufacturing Co., Ltd., Hsinchu (TW)

(72) Inventors: Fan Hsuan Chien, Tainan City (TW); Su-Yu Yeh, Tainan City (TW); Teng-Ta Hung, Kaohsiung City (TW); Chun-Jen Chen, New Taipei City (TW); Pei Yen Cheng, Tainan City (TW); Shih-Chi Lin, Hsinchu (TW)

(21) Appl. No.: 18/348,967

(22) Filed: Jul. 7, 2023

(51) Int. Cl. H01L 21/8234; H01L 27/088; H01L 29/78

(52) U.S. Cl. CPC H01L 21/823481; H01L 21/823431; H01L 27/0886; H01L 29/7846

(57) ABSTRACT

A method includes etching a gate stack to form a trench extending through the gate stack, the gate stack including a metal gate electrode and a gate dielectric, wherein forming the trench removes a portion of the gate stack to separate the gate stack into a first gate stack portion and a second gate stack portion; extending the trench through an isolation region under the gate stack and into a semiconductor substrate under the isolation region; conformally depositing a first dielectric material on surfaces in the trench; and depositing a second dielectric material on the first dielectric material to fill the trench, wherein the first dielectric material is a more flexible material than the second dielectric material.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a FinFET in a three-dimensional view, in accordance with some embodiments.

FIGS. 2, 3, 4, 5, 6, 7, 8, 9, 10A, 10B, 11, 12A, 12B, 13A, 13B, 14, 15A, 15B, 16, 17A, 17B, 18, 19A, 19B, 20, 21A, and 21B illustrate various views of intermediate stages in the manufacturing of FinFETs, in accordance with some embodiments.

FIGS. 22, 23, 24A, 24B, 24C, 25A, 25B, 25C, 26A, 26B, 26C, 27A, 27B, 27C, 28A, 28B, 28C, 29A, 29B, 29C, and 29D illustrate various views of intermediate stages in the manufacturing of gate isolation regions, in accordance with some embodiments.

FIGS. 30A, 30B, 30C, and 30D illustrate cross-sectional views of intermediate stages in the manufacturing of FinFETs, in accordance with some embodiments.

FIGS. 31 and 32 illustrate cross-sectional views of FinFET devices in accordance with other embodiments.

FIG. 33 illustrates a cross-sectional view of nano-structure transistor devices in accordance with other embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In the illustrated embodiments, the formation of Fin Field-Effect Transistors (FinFETs) is used as an example to explain the concept of the present disclosure. Other types of transistors such as planar transistors, nano-structure transistors (e.g., nano-FETs, nanosheet FETs, nanowire FETs, Gate-All-Around (GAA) transistors, or the like), or the like may also adopt the concept of the present disclosure. Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

FinFET devices can be formed by forming semiconductor strips (i.e., fins) from a substrate and forming a gate over and perpendicular to the semiconductor strips. These semiconductor strips or gates may subsequently be cut into various lengths or sizes to provide different FinFET transistors based on particular design needs. Rather than cut a dummy gate prior to replacing the dummy gate with a replacement gate, embodiment processes use a gate cutting technique which cuts a replacement gate (e.g., a metal gate) to form distinct gates over different adjacent FinFET transistors. Isolation regions are formed in the cuts by depositing a relatively flexible liner material and then filling the cut with a dielectric material. By first depositing the liner material, stresses between the dielectric material, the neighboring replacement gates, and the underlying substrate may be reduced. This can allow for less deformation of the cut and allow for improved deposition of the dielectric material. Additionally, the use of a liner material as described herein can allow for smaller and more reproducible isolation regions within the cuts.

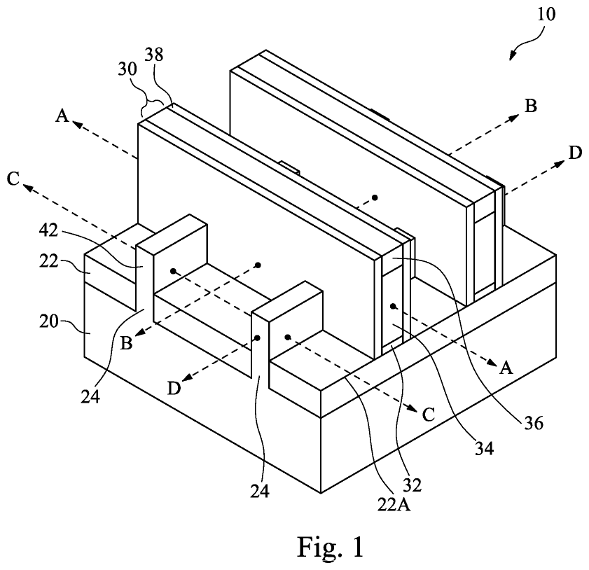

FIG. 1 illustrates an example of a FinFET in a three-dimensional view, in accordance with some embodiments. The FinFET comprises a fin 24 on a substrate 20 (e.g., a semiconductor substrate). Isolation regions 22 are disposed in the substrate 20, and the fin 24 protrudes above and from between neighboring isolation regions 22. Although the isolation regions 22 are described/illustrated as being separate from the substrate 20, as used herein the term “substrate” may be used to refer to just the semiconductor substrate or a semiconductor substrate inclusive of isolation regions. Additionally, the fin 24 may be a single continuous material, or the fin 24 and/or the substrate 20 may comprise a plurality of materials. In this context, the fin 24 refers to the portion extending between the neighboring isolation regions 22. In other embodiments, a dielectric fin (not shown in the figure) may be formed, for example, by etching a fin 24 to form a recess and then filling the recess with a dielectric material.

A gate dielectric layer 32 is along sidewalls and over a top surface of the fin 24, and a gate electrode 34 is over the gate dielectric layer 32. In this illustration, the gate electrode 34 and gate dielectric layer 32 may be dummies, and may be replaced in with a replacement gate in a subsequent process. A mask 36 is over the gate electrode 34. Epitaxial source/drain regions 42 are disposed in opposite sides of the fin 24 with respect to the gate dielectric layer 32 and gate electrode 34. The gate dielectric layer 32 and gate electrode 34, along with any interfacial layers (not shown) are taken together as the gate stack 30. A gate spacer 38 disposed on either side of the gate stack 30 between the gate stack 30 and the epitaxial source/drain regions 42.

FIG. 1 further illustrates reference cross-sections that are used in later figures. Cross-section A-A is along a longitudinal axis of the gate electrode 34 and in a direction, for example, perpendicular to the direction of current flow between the epitaxial source/drain regions 42 of the FinFET. Cross-section B-B is perpendicular to cross-section A-A and is along a longitudinal axis of the fin 24 and in a direction of, for example, a current flow between the epitaxial source/drain regions 42 of the FinFET. Cross-section C-C is parallel to cross-section A-A and extends through an epitaxial source/drain region 42 of the FinFET. Cross section D-D is parallel to cross-section B-B and extends across gate stacks 30 but between neighboring epitaxial source/drain regions 42 of the FinFET on the same side of the gate electrode 34. Subsequent figures refer to these reference cross-sections for clarity.

Some embodiments discussed herein are discussed in the context of FinFETs formed using a gate-last process. In other embodiments, a gate-first process may be used. Also, some embodiments contemplate aspects used in planar devices, such as planar FETs. Source/drain region(s) may refer to a source or a drain, individually or collectively dependent upon the context.

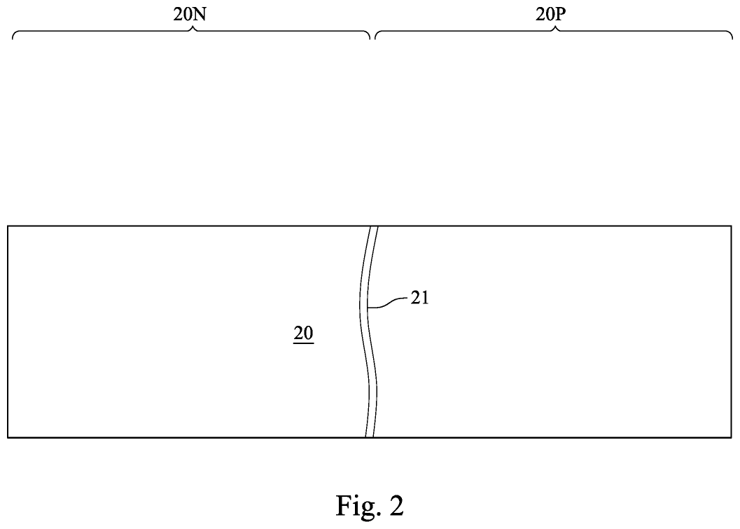

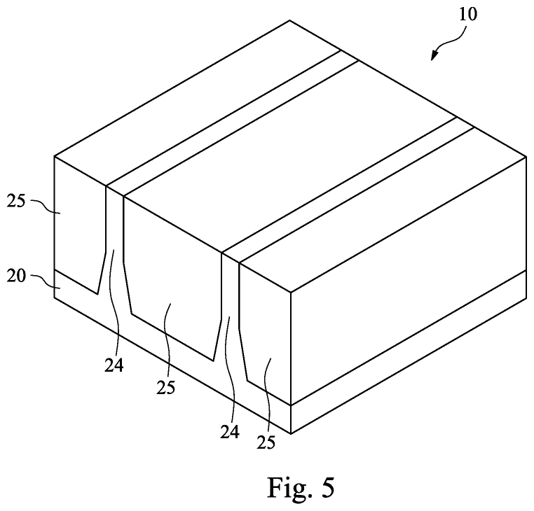

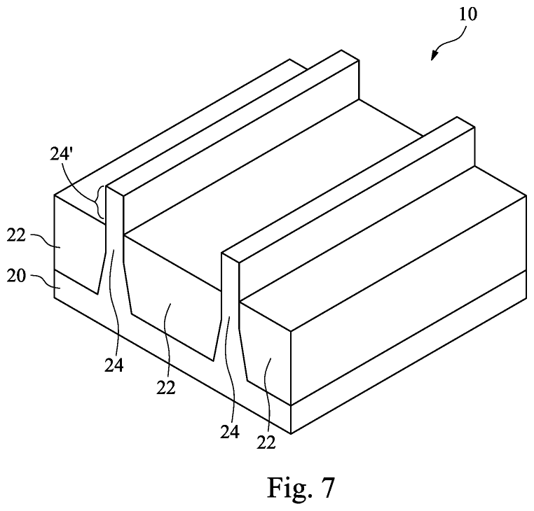

FIGS. 2 through 8 are various views of intermediate stages in the manufacturing of FinFETs through a the process forming fins in a substrate, in accordance with some embodiments. FIGS. 2, 3, 4, 6, and 8 are illustrated along the reference cross-section A-A. FIGS. 5 and 7 are perspective views.

In FIG. 2, a substrate 20 is provided. The substrate 20 may be a semiconductor substrate, such as a bulk semiconductor, a semiconductor-on-insulator (SOI) substrate, or the like, which may be doped (e.g., with a p-type or an n-type dopant) or undoped. The substrate 20 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 20 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

The substrate 20 has a region 20N and a region 20P. The region 20N can be for forming n-type devices, such as NMOS transistors, e.g., n-type FinFETs. The region 20P can be for forming p-type devices, such as PMOS transistors, e.g., p-type FinFETs. The region 20N may be physically separated from the region 20P (as illustrated by divider 21), and any number of device features (e.g., other active devices, doped regions, isolation structures, etc.) may be disposed between the region 20N and the region 20P.

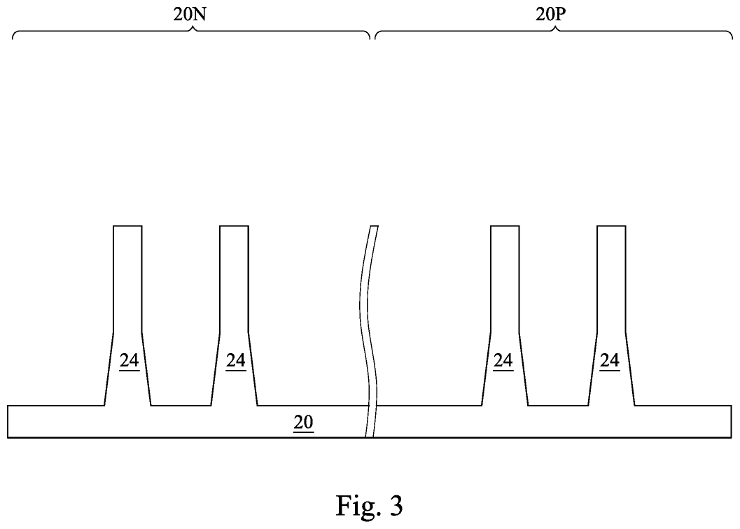

In FIG. 3, fins 24 are formed in the substrate 20. The fins 24 are semiconductor strips. In some embodiments, the fins 24 may be formed in the substrate 20 by etching trenches in the substrate 20. The etching may be any acceptable etch process, such as a reactive ion etch (RIE), neutral beam etch (NBE), the like, or a combination thereof. The etch may be anisotropic.

The fins 24 may be patterned by any suitable method. For example, the fins 24 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins. In some embodiments, the mask (or other layer) may remain on the fins 24.

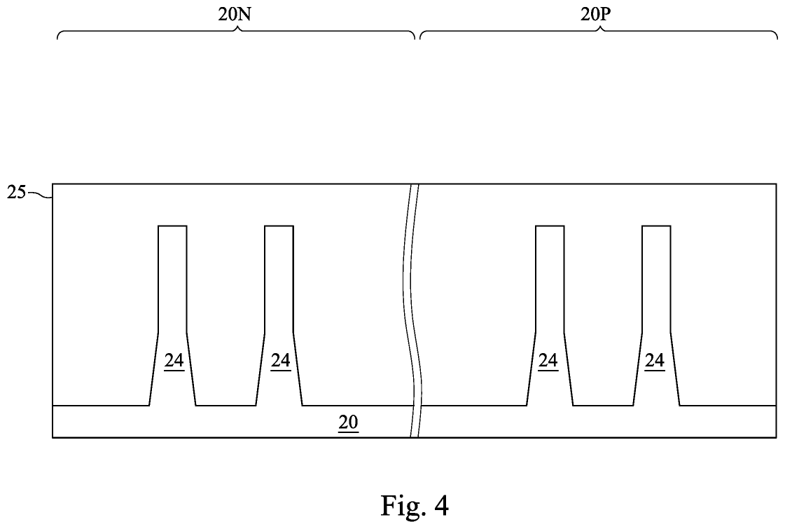

In FIG. 4, an insulation material 25 is formed over the substrate 20 and between neighboring fins 24. The insulation material 25 may be an oxide, such as silicon oxide, a nitride, the like, or a combination thereof, and may be formed by a high density plasma chemical vapor deposition (HDP-CVD), a flowable CVD (FCVD) (e.g., a CVD-based material deposition in a remote plasma system and post curing to make it convert to another material, such as an oxide), the like, or a combination thereof. Other insulation materials formed by any acceptable process may be used. In the illustrated embodiment, the insulation material 25 is silicon oxide formed by a FCVD process. An anneal process may be performed once the insulation material is formed. In an embodiment, the insulation material 25 is formed such that excess insulation material 25 covers the fins 24. Although the insulation material 25 is illustrated as a single layer, some embodiments may utilize multiple layers. For example, in some embodiments a liner (not shown) may first be formed along a surface of the substrate 20 and the fins 24. Thereafter, a fill material, such as those discussed above may be formed over the liner.

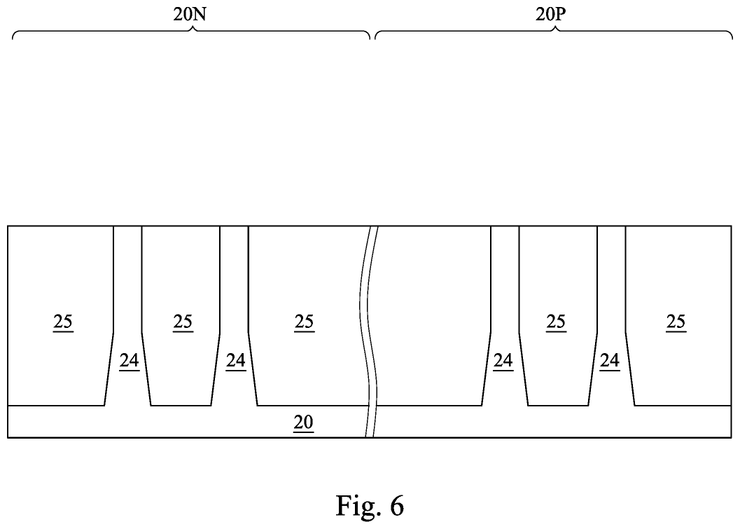

FIG. 5 illustrates a perspective view which may be applicable for either region 20N or region 20P. FIG. 6 illustrates a cross-sectional view of the structure shown in FIG. 5 along the reference cross-section A-A as illustrated in FIG. 1. In FIGS. 5 and 6, a removal process is applied to the insulation material 25 to remove excess insulation material 25 over the fins 24. In some embodiments, a planarization process such as a chemical mechanical polish (CMP), an etch-back process, combinations thereof, or the like may be utilized. The planarization process exposes the fins 24 such that top surfaces of the fins 24 and the insulation material 25 are level after the planarization process is complete. In embodiments in which a mask remains on the fins 24, the planarization process may expose the mask or remove the mask such that top surfaces of the mask or the fins 24, respectively, and the insulation material 25 are level after the planarization process is complete.

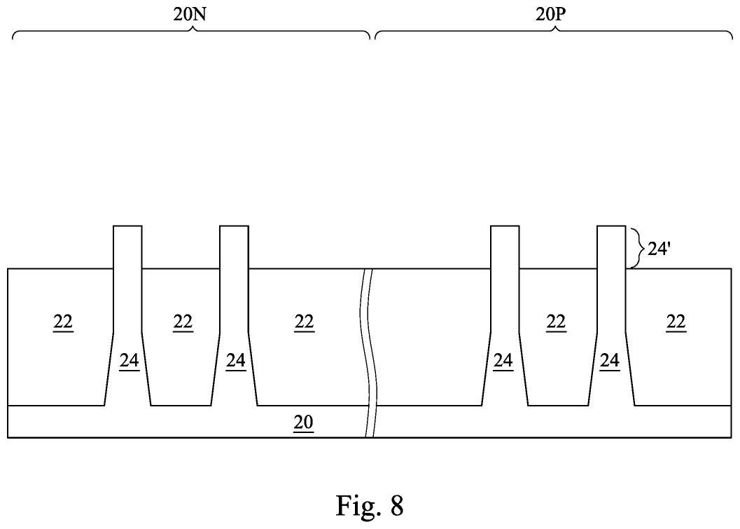

FIG. 7 illustrates a perspective view which may be applicable for either region 20N or region 20P. FIG. 8 illustrates a cross-sectional view of the structure shown in FIG. 7 along the reference cross-section A-A as illustrated in FIG. 1. In FIGS. 7 and 8, the insulation material 25 is recessed to form Shallow Trench Isolation (STI) regions (isolation regions 22). The insulation material 25 is recessed such that upper portions (channel region 24′) of fins 24 in the region 50N and in the region 50P protrude from between neighboring isolation regions 22. Further, the top surfaces of the isolation regions 22 may have a flat surface as illustrated, a convex surface, a concave surface (such as dishing), or a combination thereof. The top surfaces of the isolation regions 22 may be formed flat, convex, and/or concave by an appropriate etch. The isolation regions 22 may be recessed using an acceptable etching process, such as one that is selective to the material of the insulation material 25 (e.g., etches the material of the insulation material 25 at a faster rate than the material of the fins 24). For example, an oxide removal using, for example, dilute hydrofluoric (dHF) acid may be used.

The process described with respect to FIGS. 2 through 8 is just one example of how the fins 24 may be formed. In some embodiments, the fins 24 may be formed by an epitaxial growth process. For example, a dielectric layer can be formed over a top surface of the substrate 20, and trenches can be etched through the dielectric layer to expose the underlying substrate 20. Homoepitaxial structures can be epitaxially grown in the trenches, and the dielectric layer can be recessed such that the homoepitaxial structures protrude from the dielectric layer to form fins. Additionally, in some embodiments, heteroepitaxial structures can be used for the fins 24. For example, the fins 24 in FIGS. 7 through 8 can be recessed, and a material different from the fins 24 may be epitaxially grown over the recessed fins 24. In such embodiments, the fins 24 comprise the recessed material as well as the epitaxially grown material disposed over the recessed material. In an even further embodiment, a dielectric layer can be formed over a top surface of the substrate 20, and trenches can be etched through the dielectric layer. Heteroepitaxial structures can then be epitaxially grown in the trenches using a material different from the substrate 20, and the dielectric layer can be recessed such that the heteroepitaxial structures protrude from the dielectric layer to form the fins 24. In some embodiments where homoepitaxial or heteroepitaxial structures are epitaxially grown, the epitaxially grown materials may be in situ doped during growth, which may obviate prior and subsequent implantations although in situ and implantation doping may be used together.

Still further, it may be advantageous to epitaxially grow a material in region 20N (e.g., an NMOS region) different from the material in region 20P (e.g., a PMOS region). In various embodiments, upper portions of the fins 24 may be formed from silicon-germanium (SiₓGe₁₋ₓ, where x can be in the range of 0 to 1), silicon carbide, pure or substantially pure germanium, a III-V compound semiconductor, a II-VI compound semiconductor, or the like. For example, the available materials for forming III-V compound semiconductor include, but are not limited to, indium arsenide, aluminum arsenide, gallium arsenide, indium phosphide, gallium nitride, indium gallium arsenide, indium aluminum arsenide, gallium antimonide, aluminum antimonide, aluminum phosphide, gallium phosphide, and the like.

Further in FIG. 8, appropriate wells (not shown) may be formed in the fins 24 and/or the substrate 20. In some embodiments, a P well may be formed in the region 20N, and an N well may be formed in the region 20P. In some embodiments, a P well or an N well are formed in both the region 20N and the region 20P.

In the embodiments with different well types, the different implant steps for the region 20N and the region 20P may be achieved using a photoresist or other masks (not shown). For example, a photoresist may be formed over the fins 24 and the isolation regions 22 in the region 20N. The photoresist is patterned to expose the region 20P of the substrate 20, such as a PMOS region. The photoresist can be formed by using a spin-on technique and can be patterned using acceptable photolithography techniques. Once the photoresist is patterned, an n-type impurity implant is performed in the region 20P, and the photoresist may act as a mask to substantially prevent n-type impurities from being implanted into the region 20N, such as an NMOS region. The n-type impurities may be phosphorus, arsenic, antimony, or the like implanted in the region to a concentration of equal to or less than 1018 cm⁻³, such as between about 1016 cm⁻³ and about 1018 cm⁻³. After the implant, the photoresist is removed, such as by an acceptable ashing process.

Following the implanting of the region 20P, a photoresist is formed over the fins 24 and the isolation regions 22 in the region 20P. The photoresist is patterned to expose the region 20N of the substrate 20, such as the NMOS region. The photoresist can be formed by using a spin-on technique and can be patterned using acceptable photolithography techniques. Once the photoresist is patterned, a p-type impurity implant may be performed in the region 20N, and the photoresist may act as a mask to substantially prevent p-type impurities from being implanted into the region 20P, such as the PMOS region. The p-type impurities may be boron, boron fluoride, indium, or the like implanted in the region to a concentration of equal to or less than 1018 cm⁻³, such as between about 1016 cm⁻³ and about 1018 cm⁻³. After the implant, the photoresist may be removed, such as by an acceptable ashing process.

After the implants of the region 20N and the region 20P, an anneal may be performed to repair implant damage and to activate the p-type and/or n-type impurities that were implanted. In some embodiments, the grown materials of epitaxial fins may be in situ doped during growth, which may obviate the implantations, although in situ and implantation doping may be used together.

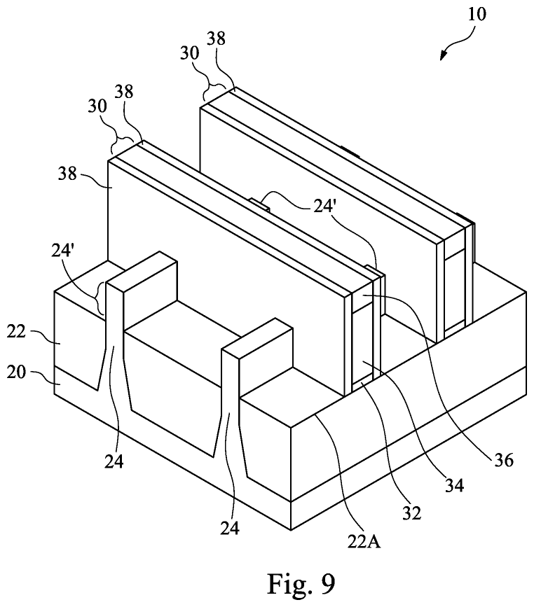

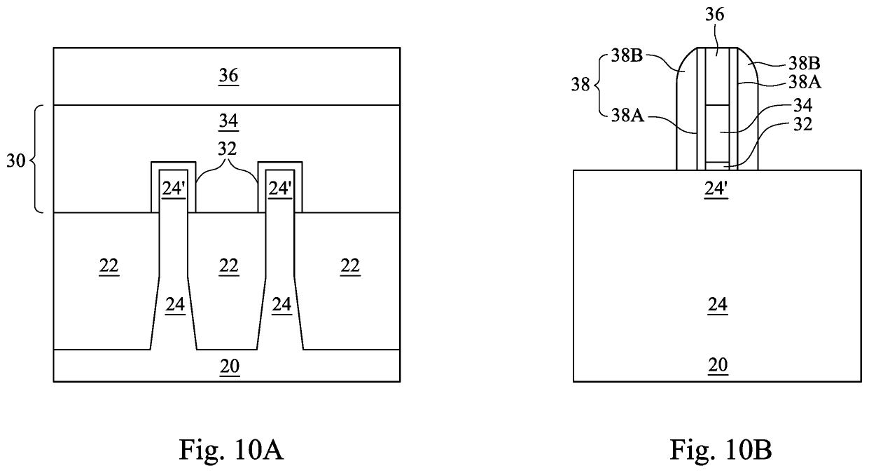

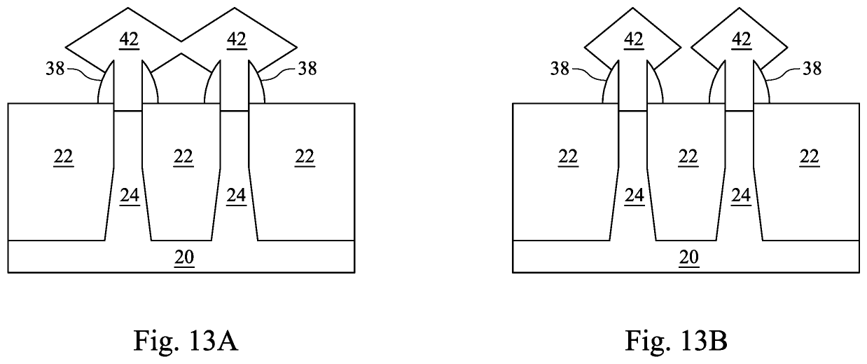

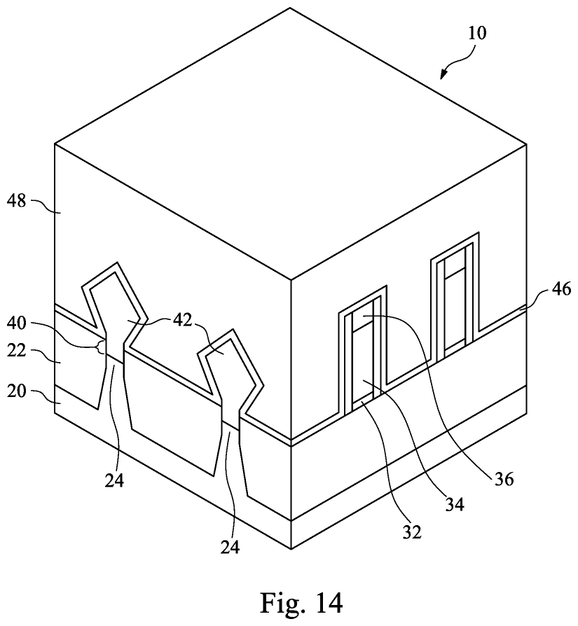

FIGS. 9 through 21B illustrate various additional intermediate stages in the manufacturing of FinFET devices, in accordance with some embodiments. FIGS. 9 through 22 illustrate features in either of the region 20N and the region 20P and each will not be separately illustrated. Differences (if any) in the structures of the region 20N and the region 20P are described in the text accompanying each figure. With reference to FIG. 1 for the reference cross-sections A-A, B-B, C-C, and D-D, FIGS. 10A, 12A, 15A, 17A, 19A, and 21A are illustrated along reference cross-section A-A. FIGS. 13A and 13B are illustrated along reference cross-section C-C. FIGS. 10B, 12B, 15B, 17B, 19B, and 21B are illustrated along reference cross-section D-D.

FIG. 10A illustrates a cross-sectional view of the structure shown in FIG. 9 along the reference cross-section A-A as illustrated in FIG. 1. FIG. 10B illustrates a cross-sectional view of the structure shown in FIG. 9 along the reference cross-section D-D as illustrated in FIG. 1. In FIGS. 9, 10A, and 10B, a dummy dielectric layer is formed on the fins 24. The dummy dielectric layer may be, for example, silicon oxide, silicon nitride, a combination thereof, or the like, and may be deposited or thermally grown according to acceptable techniques. A dummy gate layer is formed over the dummy dielectric layer, and a mask layer is formed over the dummy gate layer. The dummy gate layer may be deposited over the dummy dielectric layer and then planarized, such as by a CMP. The mask layer may be deposited over the dummy gate layer. The mask layer may be patterned using acceptable photolithography and etching techniques to form masks 36. The pattern of the masks 36 then may be transferred to the dummy gate layer to form dummy gates 34. In some embodiments (not illustrated), the pattern of the masks 36 may also be transferred to the dummy dielectric layer by an acceptable etching technique to form gate dielectric layer 32. Together the gate dielectric layer 32 and dummy gates 34 form dummy gate stacks 30. The dummy gate stacks 30 cover respective channel regions 24′ of the fins 24. The pattern of the masks 36 may be used to physically separate each of the dummy gate stacks 30 from adjacent dummy gate stacks. The dummy gate stacks 30 may also have a lengthwise direction substantially perpendicular to the lengthwise direction of respective epitaxial fins 24.

The dummy gates 34 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gates 34 formed from the dummy gate layer may be deposited by physical vapor deposition (PVD), CVD, sputter deposition, or other techniques known and used in the art for depositing the selected material. The dummy gates 34 may be made of other materials that have a high etching selectivity from the etching of isolation regions 22. The mask 36 formed from the mask layer may include, for example, silicon nitride, silicon oxynitride, or the like. In some embodiments, a single dummy gate layer and a single mask layer are formed across the region 20N and the region 20P. In other embodiments, each region 20N and region 20P may have their own independent dummy gate layer and mask layer. It is noted that the gate dielectric layer 32 is shown covering only the fins 24 for illustrative purposes only.

Also in FIGS. 9, 10A, and 10B, gate seal spacers 38A can be formed on exposed surfaces of the dummy gates stacks 30, the masks 36, and/or the fins 24 (the channel regions 24′). A thermal oxidation or a deposition followed by an anisotropic etch may form the gate seal spacers 38A. The gate seal spacers 38A may be formed of silicon oxide, silicon nitride, silicon oxynitride, or the like.

After the formation of the gate seal spacers 38A, implants for lightly doped source/drain (LDD) regions (not explicitly illustrated) may be performed. In the embodiments with different device types, similar to the implants discussed above with respect to FIGS. 7 and 8, a mask, such as a photoresist, may be formed over the region 20N, while exposing the region 20P, and appropriate type (e.g., p-type) impurities may be implanted into the exposed channel regions 24′ in the region 20P. The mask may then be removed. Subsequently, a mask, such as a photoresist, may be formed over the region 20P while exposing the region 20N, and appropriate type impurities (e.g., n-type) may be implanted into the exposed channel regions 24′ in the region 20N. The mask may then be removed. The n-type impurities may be the any of the n-type impurities previously discussed, and the p-type impurities may be the any of the p-type impurities previously discussed. The lightly doped source/drain regions may have a concentration of impurities of from about 10¹⁵ cm⁻³ to about 10¹⁹ cm⁻³. An anneal may be used to repair implant damage and to activate the implanted impurities.

Also in FIGS. 9, 10A, and 10B, gate spacers 38B are formed on the gate seal spacers 38A along sidewalls of the dummy gates stacks 30 and the masks 36. The gate spacers 38B may be formed by conformally depositing an insulating material and subsequently anisotropically etching the insulating material. The insulating material of the gate spacers 38B may be silicon oxide, silicon nitride, silicon oxynitride, silicon carbonitride, a combination thereof, or the like.

The gate seal spacers 38A and gate spacers 38B may, for simplicity, together be referred to as gate spacers 38. It is noted that the above disclosure generally describes a process of forming spacers and LDD regions. Other processes and sequences may be used. For example, fewer or additional spacers may be utilized, different sequence of steps may be utilized (e.g., the gate seal spacers 38A may not be etched prior to forming the gate spacers 38B, yielding “L-shaped” gate seal spacers, spacers may be formed and removed, and/or the like. Furthermore, the n-type and p-type devices may be formed using a different structures and steps. For example, LDD regions for n-type devices may be formed prior to forming the gate seal spacers 38A while the LDD regions for p-type devices may be formed after forming the gate seal spacers 38A.

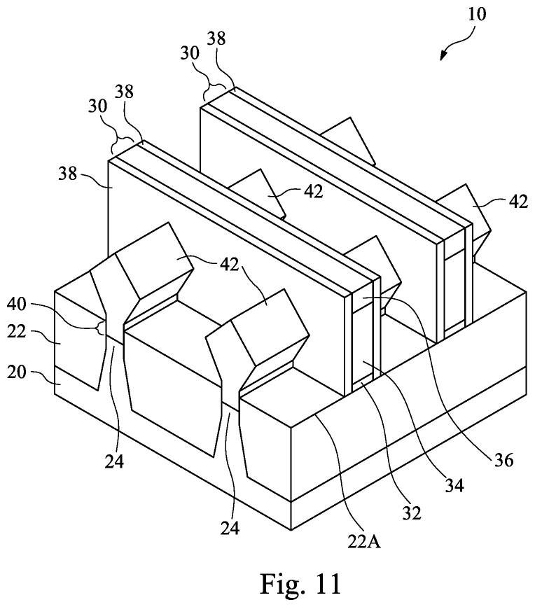

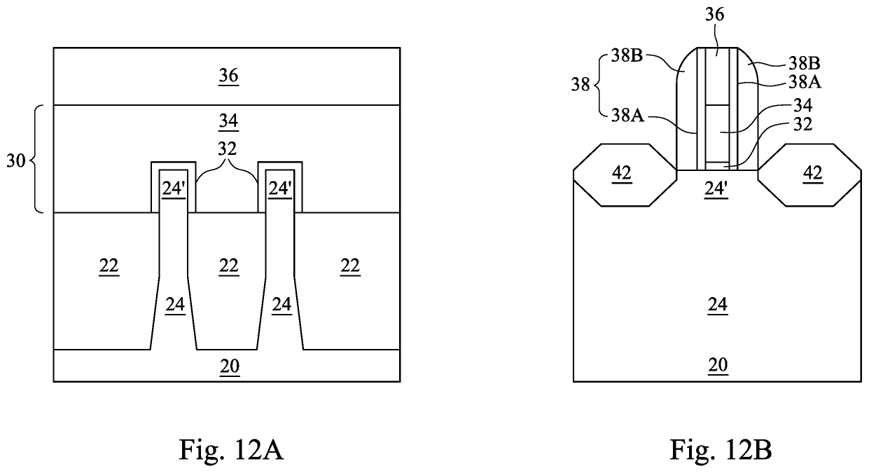

FIG. 12A illustrates a cross-sectional view of the structure shown in FIG. 11 along the reference cross-section A-A as illustrated in FIG. 1. FIG. 12B illustrates a cross-sectional view of the structure shown in FIG. 11 along the reference cross-section D-D as illustrated in FIG. 1. FIGS. 13A and 13B illustrate cross-sectional views of the structure shown in FIG. 11 along the reference cross-section C-C as illustrated in FIG. 1. In FIGS. 11, 12A, 12B, 13A, and 13B epitaxial source/drain regions 42 are formed in the fins 24 to exert stress in the respective channel regions 24′, thereby improving performance. The epitaxial source/drain regions 42 are formed in the fins 24 such that each dummy gate stack 30 is disposed between respective neighboring pairs of the epitaxial source/drain regions 42. In some embodiments the epitaxial source/drain regions 42 may extend into, and may also penetrate through, the fins 24. In some embodiments, the gate spacers 38 are used to separate the epitaxial source/drain regions 42 from the dummy gate stacks 30 by an appropriate lateral distance so that the epitaxial source/drain regions 42 do not short out subsequently formed gates of the resulting FinFETs.

The epitaxial source/drain regions 42 in the region 20N, e.g., the NMOS region, may be formed by masking the region 20P, e.g., the PMOS region, and etching source/drain regions of the fins 24 in the region 20N to form recesses in the fins 24. Then, the epitaxial source/drain regions 42 in the region 20N are epitaxially grown in the recesses. The epitaxial source/drain regions 42 may include any acceptable material, such as appropriate for n-type FinFETs. For example, if the fin 24 is silicon, the epitaxial source/drain regions 42 in the region 20N may include materials exerting a tensile strain in the channel region 24′, such as silicon, silicon carbide, phosphorous-doped silicon carbide, silicon phosphide, or the like. The epitaxial source/drain regions 42 in the region 20N may have surfaces raised from respective surfaces of the fins 24 and may have facets.

The epitaxial source/drain regions 42 in the region 20P, e.g., the PMOS region, may be formed by masking the region 20N, e.g., the NMOS region, and etching source/drain regions of the fins 24 in the region 20P are etched to form recesses in the fins 24. Then, the epitaxial source/drain regions 42 in the region 20P are epitaxially grown in the recesses. The epitaxial source/drain regions 42 may include any acceptable material, such as appropriate for p-type FinFETs. For example, if the fin 24 is silicon, the epitaxial source/drain regions 42 in the region 20P may comprise materials exerting a compressive strain in the channel region 24′, such as silicon-germanium, boron doped silicon-germanium, germanium, germanium tin, or the like. The epitaxial source/drain regions 42 in the region 20P may also have surfaces raised from respective surfaces of the fins 24 and may have facets.

The epitaxial source/drain regions 42 and/or the fins 24 may be implanted with dopants to form source/drain regions, similar to the process previously discussed for forming lightly-doped source/drain regions, followed by an anneal. The epitaxial source/drain regions 42 may have an impurity concentration of between about 10¹⁹ cm⁻³ and about 1021 cm⁻³. The n-type and/or p-type impurities for epitaxial source/drain regions 42 may be any of the impurities previously discussed. In some embodiments, the epitaxial source/drain regions 42 may be in situ doped during growth.

As a result of the epitaxy processes used to form the epitaxial source/drain regions 42 in the region 20N and the region 20P, upper surfaces of the epitaxial source/drain regions have facets which expand laterally outward beyond sidewalls of the fins 24. In some embodiments, these facets cause adjacent epitaxial source/drain regions 42 of a same FinFET to merge as illustrated by FIG. 13A. In other embodiments, adjacent epitaxial source/drain regions 42 remain separated after the epitaxy process is completed as illustrated by FIG. 13B. In the embodiments illustrated in FIGS. 13A and 13B, gate spacers 38 are formed covering a portion of the sidewalls of the fins 24 (the channel region 24′) that extend above the STI regions 22 thereby blocking the epitaxial growth. In some other embodiments, the spacer etch used to form the gate spacers 38 may be adjusted to remove the spacer material to allow the epitaxially source/drain regions 42 to extend to the surface of the isolation regions 22.

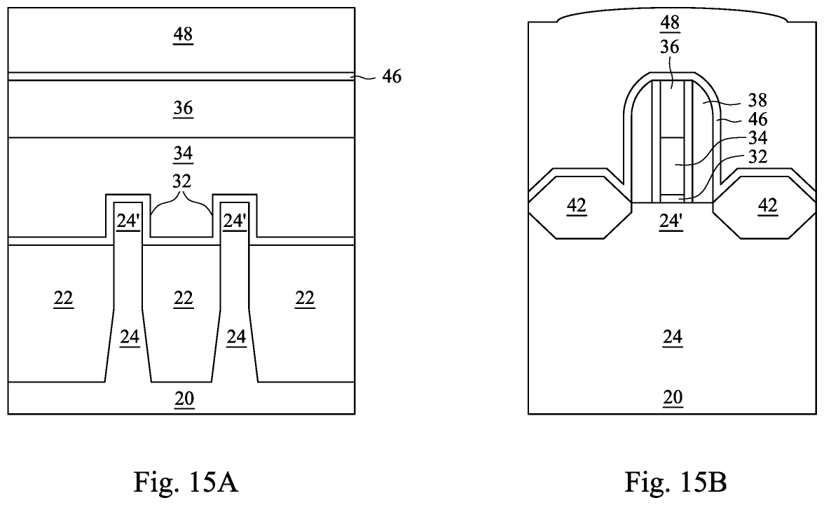

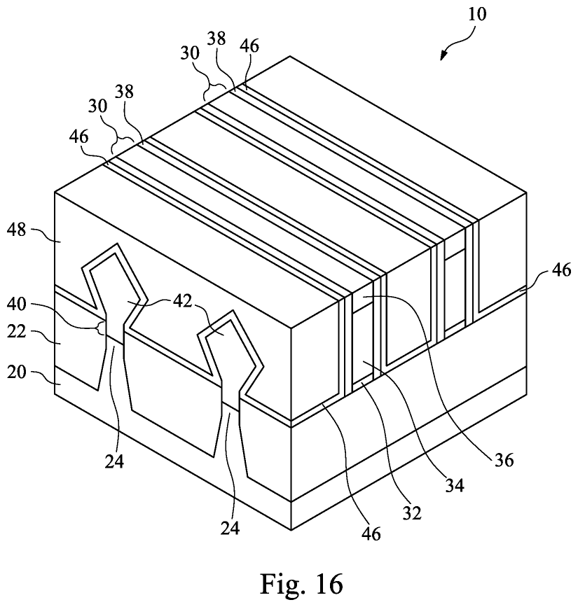

FIG. 15A illustrates a cross-sectional view of the structure shown in FIG. 14 along the reference cross-section A-A as illustrated in FIG. 1. FIG. 15B illustrates a cross-sectional view of the structure shown in FIG. 14 along the reference cross-section D-D as illustrated in FIG. 1. In FIGS. 14, 15A, and 15B, a first interlayer dielectric (ILD) 48 is deposited over the structure illustrated in FIGS. 11, 12A, and 12B. The first ILD 48 may be formed of a dielectric material, and may be deposited by any suitable method, such as CVD, plasma-enhanced CVD (PECVD), or FCVD.

Dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, a contact etch stop layer (CESL) 46 is disposed between the first ILD 48 and the epitaxial source/drain regions 42, the masks 36, and the gate spacers 38. The CESL 46 may comprise a dielectric material, such as, silicon nitride, silicon oxide, silicon oxynitride, or the like, having a different etch rate than the material of the overlying the first ILD 48.

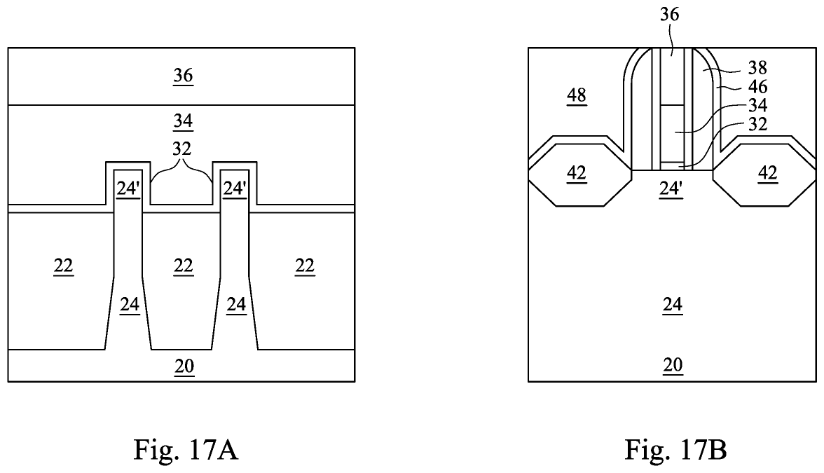

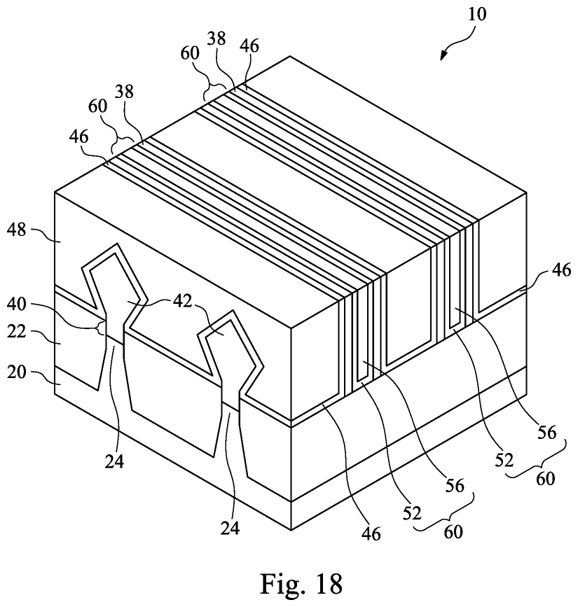

FIG. 17A illustrates a cross-sectional view of the structure shown in FIG. 16 along the reference cross-section A-A as illustrated in FIG. 1. FIG. 17B illustrates a cross-sectional view of the structure shown in FIG. 16 along the reference cross-section D-D as illustrated in FIG. 1. In FIGS. 16, 17A, and 17B, a planarization process, such as a CMP, may be performed to level the top surface of the first ILD 48 with the top surfaces of the dummy gate stacks 30 or the masks 36 (as shown, for example, in FIG. 17). The planarization process may also remove the masks 36 (or a portion thereof) on the dummy gate stacks 30, and portions of the gate spacers 38 along sidewalls of the masks 36. After the planarization process, the masks 36 may remain, in which case top surfaces of the masks 36, top surfaces of the gate spacers 38, and the top surface of the first ILD 48 are leveled with each other. In some embodiments, top surfaces of the dummy gate stacks 30, the gate spacers 38, and the first ILD 48 are levelled as a result of the planarization process. In such embodiments, the top surfaces of the dummy gates 72 are exposed through the first ILD 48.

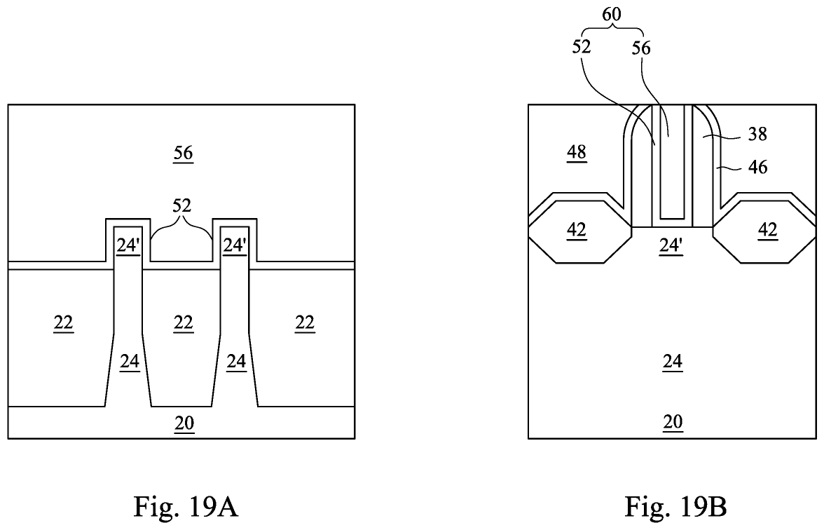

FIG. 19A illustrates a cross-sectional view of the structure shown in FIG. 18 along the reference cross-section A-A as illustrated in FIG. 1. FIG. 19B illustrates a cross-sectional view of the structure shown in FIG. 18 along the reference cross-section D-D as illustrated in FIG. 1. FIGS. 18, 19A, and 19B illustrate a gate replacement process. The dummy gates 34, the masks 36 if present, and optionally the gate dielectric layer 32, are removed in an etching step(s) and replaced with replacement gates. In some embodiments, the masks 36 if present and dummy gates 34 are removed by an anisotropic dry etch process. For example, the etching process may include a dry etch process using reaction gas(es) that selectively etch the masks 36 and then the dummy gates 34 without etching the first ILD 48 or the gate spacers 38. Each recess exposes and/or overlies a channel region 24′ of a respective fin 24 (the upper portion of the fin 24). Each channel region 24′ is disposed between neighboring pairs of the epitaxial source/drain regions 42. During the removal, the gate dielectric layer 32 may be used as an etch stop layer when the dummy gates 34 are etched. The gate dielectric layer 32 may then be optionally removed after the removal of the dummy gates 34.

Next, gate dielectric layers 52 and gate electrodes 56 are formed for replacement gates 60. Gate dielectric layers 52 are deposited conformally in the recesses, such as on the top surfaces and the sidewalls of the fins 24 and on sidewalls of the gate spacers 38. The gate dielectric layers 52 may also be formed on the top surface of the first ILD 48. In accordance with some embodiments, the gate dielectric layers 52 comprise silicon oxide, silicon nitride, or multilayers thereof. In some embodiments, the gate dielectric layers 52 may include a high-k dielectric material, and in these embodiments, the gate dielectric layers 52 may have a k value greater than about 7.0, and may include a metal oxide or a silicate of hafnium, aluminum, zirconium, lanthanum, manganese, barium, titanium, lead, and combinations thereof. The formation methods of the gate dielectric layers 52 may include Molecular-Beam Deposition (MBD), Atomic Layer Deposition (ALD), PECVD, and the like. In embodiments where portions of the gate dielectric layer 32 remains in the recesses, the gate dielectric layers 52 include a material of the gate dielectric layer 32 (e.g., silicon oxide).

The gate electrodes 56 are deposited over the gate dielectric layers 52, respectively, and fill the remaining portions of the recesses. The gate electrodes 56 may include a metal-containing material such as titanium nitride, titanium oxide, tantalum nitride, tantalum carbide, cobalt, ruthenium, aluminum, tungsten, combinations thereof, or multi-layers thereof. For example, although the gate electrode 56 is illustrated in FIG. 19 as having a single layer, the gate electrode 56 may comprise any number of liner layers, any number of work function tuning layers, and a fill material, all together illustrated as gate electrode 56. After the filling of the recesses, a planarization process, such as a CMP, may be performed to remove the excess portions of the gate dielectric layers 52 and the material of the gate electrodes 56, which excess portions are over the top surface of the first ILD 48. The remaining portions of material of the gate dielectric layers 52 and the gate electrodes 56 thus form replacement gates of the resulting FinFETs. The gate electrodes 56 and the gate dielectric layers 52 of the replacement gates may be collectively referred to as gate stack 60. The gate stacks may extend along sidewalls of a channel region 24′ of the fins 24.

The formation of the gate dielectric layers 52 in the region 20N and the region 20P may occur simultaneously such that the gate dielectric layers 52 in each region are formed from the same materials, and the formation of the gate electrodes 56 may occur simultaneously such that the gate electrodes 56 in each region are formed from the same materials. In some embodiments, the gate dielectric layers 52 in each region may be formed by distinct processes, such that the gate dielectric layers 52 may be different materials, and/or the gate electrodes 56 in each region may be formed by distinct processes, such that the gate electrodes 56 may be different materials. Various masking steps may be used to mask and expose appropriate regions when using distinct processes. Gate electrodes 56 may include a plurality of layers including, and not limited to, a titanium silicon nitride (TiSiN) layer, a tantalum nitride (TaN) layer, a titanium nitride (TiN) layer, a titanium aluminum (TiAl) layer, an additional TiN and/or TaN layer, and a filling metal. Some of these layers define the work function of the respective FinFET. Furthermore, the metal layers of a p-type FinFET and the metal layers of an n-type FinFET may be different from each other, so that the work functions of the metal layers are suitable for the respective p-type or n-type FinFETs. The fill material may include aluminum, tungsten, cobalt, ruthenium, or the like.

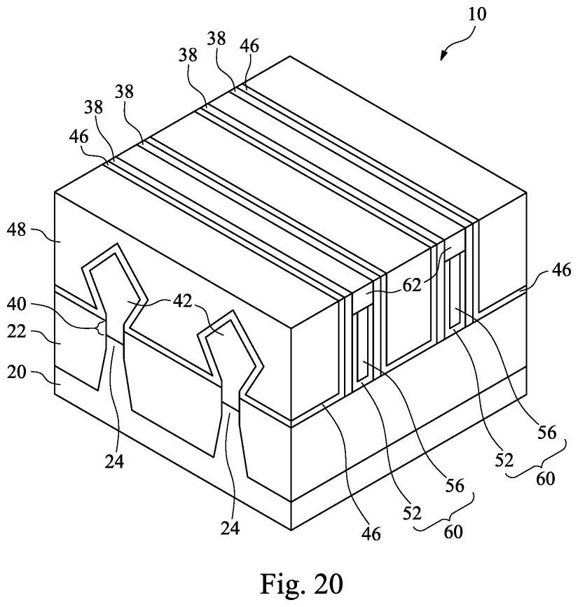

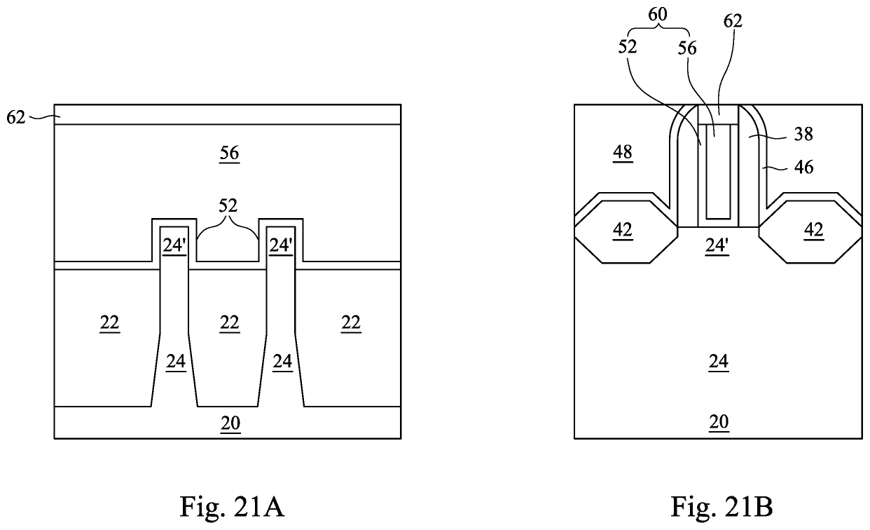

FIG. 21A illustrates a cross-sectional view of the structure shown in FIG. 20, with the cross-sectional view obtained from the plane containing line A-A as illustrated in FIG. 1. FIG. 21B illustrates a cross-sectional view of the structure shown in FIG. 20, with the cross-sectional view obtained from the plane containing line D-D as illustrated in FIG. 1. As shown in FIGS. 20, 21A, and 21B, hard masks 62 are formed. The material of hard masks 62 may be the same as or different from the materials of some of CESL 46, the first ILD 48, and/or gate spacers 38. In accordance with some embodiments, hard masks 62 are formed of silicon nitride, silicon oxynitride, silicon oxy-carbide, silicon oxy carbo-nitride, or the like. The formation of hard masks 62 may include recessing the gate stacks 60 through etching to form recesses, filling a dielectric material into the recesses, and performing a planarization to remove the excess portions of the dielectric material. The remaining portions of the dielectric material are hard masks 62.

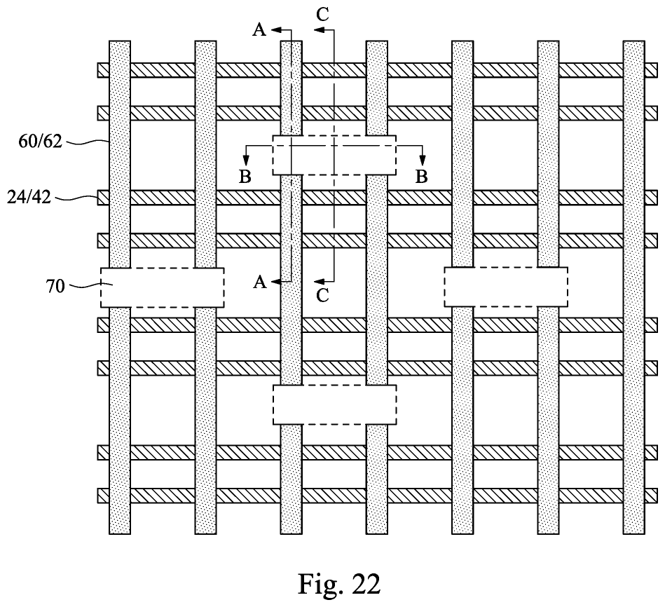

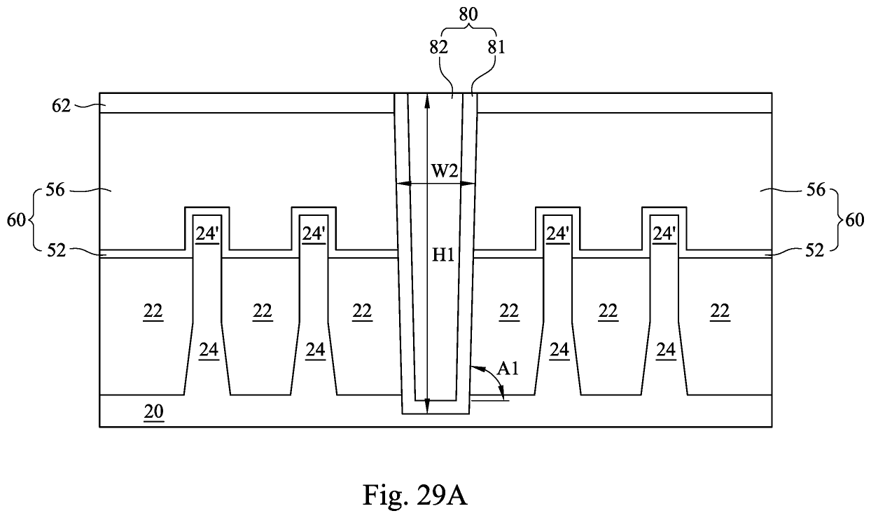

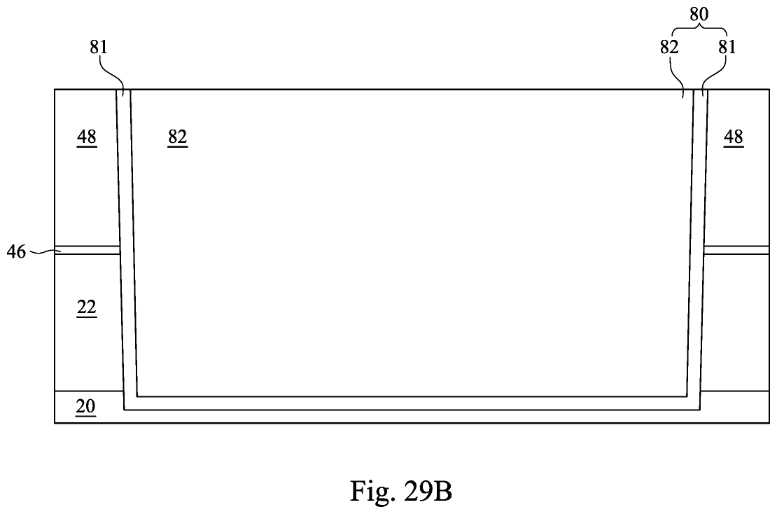

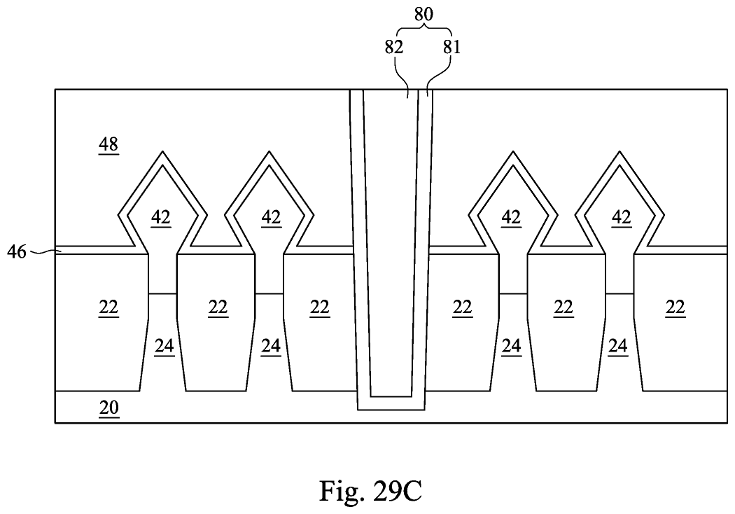

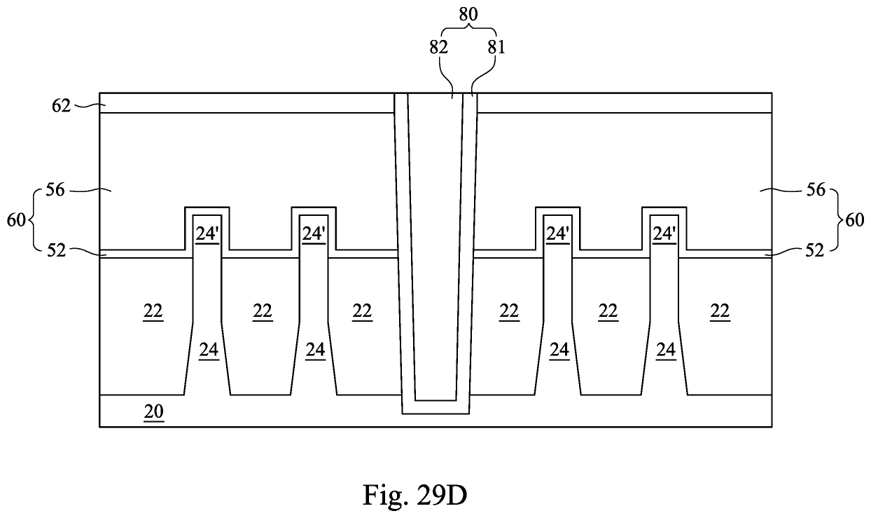

FIGS. 22, 23, 24A, 24B, 24C, 25A, 25B, 25C, 26A, 26B, 26C, 27A, 27B, 27C, 28A, 28B, 28C, 29A, 29B, 29C, 30A, 30B, 30C, and 30D illustrate a cut-metal gate process followed by a process for forming contacts. The figure numbers of the subsequent processes may include the letter “A,” “B,” “C,” or “D.” Unless specified otherwise (for example, as with FIG. 29D), the figures whose numbers having the letter “A” are cross-sectional views along the reference cross-section A-A in FIG. 1. The figures whose numbers having the letter “B” are cross-sectional views along the reference cross-section B-B in FIG. 1. The figures whose numbers having the letter “C” are cross-sectional views along the reference cross-section C-C in FIG. 1. The figures whose numbers having the letter “D” are cross-sectional views along the reference cross-section D-D in FIG. 1.

FIG. 22 illustrates a top down view of an example portion of a layout of FinFETs, in accordance with some embodiments. In this view, the ILD 48 is not shown so as to illustrate the gate stacks 60 with hard masks 62 and the fins 24 with the source/drain regions 42 more clearly. The vertical lines correspond to the gate stacks 60 with the hard masks 62. The horizontal lines correspond to the fins 24 with the source/drain regions 42 formed therein. The dashed areas correspond to openings 70 which are discussed below which are areas where one or more gates are cut. In the example embodiment below two gates are simultaneously cut in one opening 70, however, in some embodiments, multiple openings 70 may be made which each cut any number of gates, such as only one gate or ten gates. Other numbers of openings 70 may be used. The openings 70 are subsequently filled with a stress reduction liner 81 and a dielectric fill material 82 to form gate isolation regions 80, described in greater detail below. The indicated cross-sections A-A, B-B, and C-C correspond to the analogous reference cross-sections in FIG. 1.

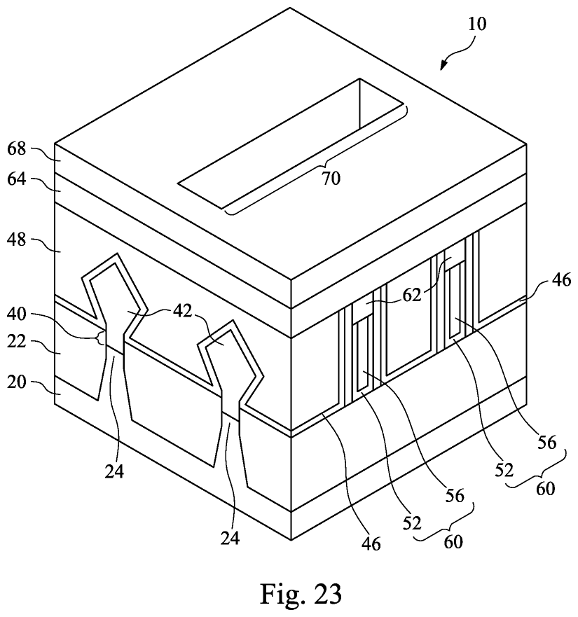

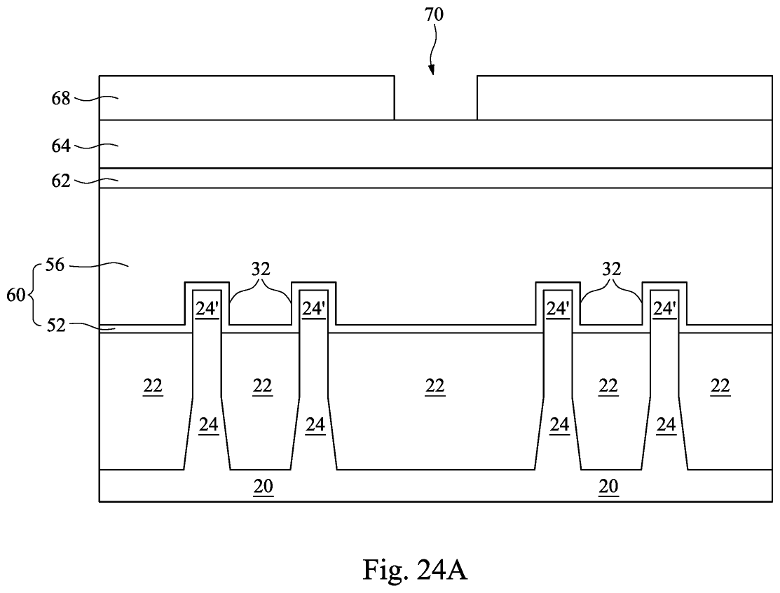

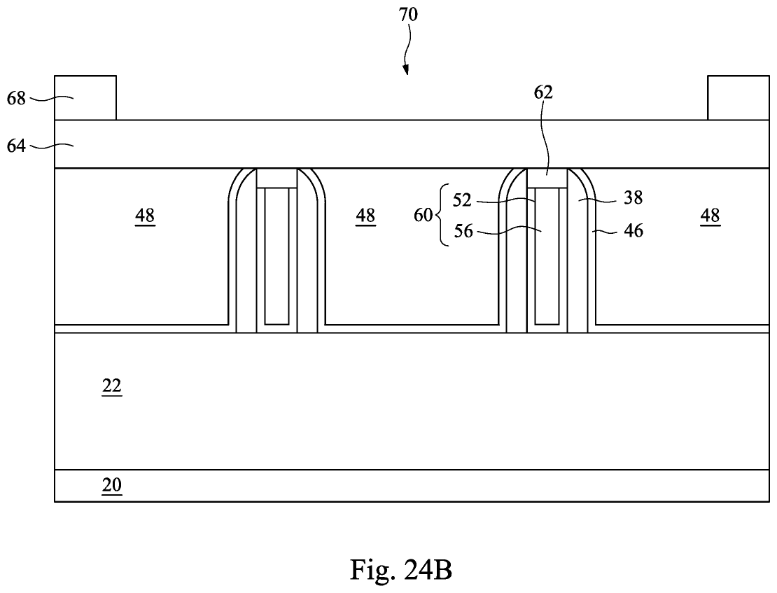

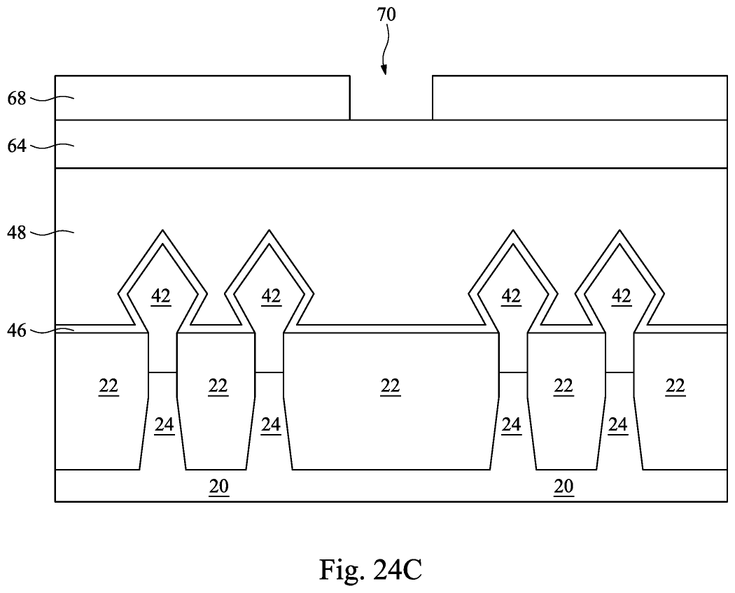

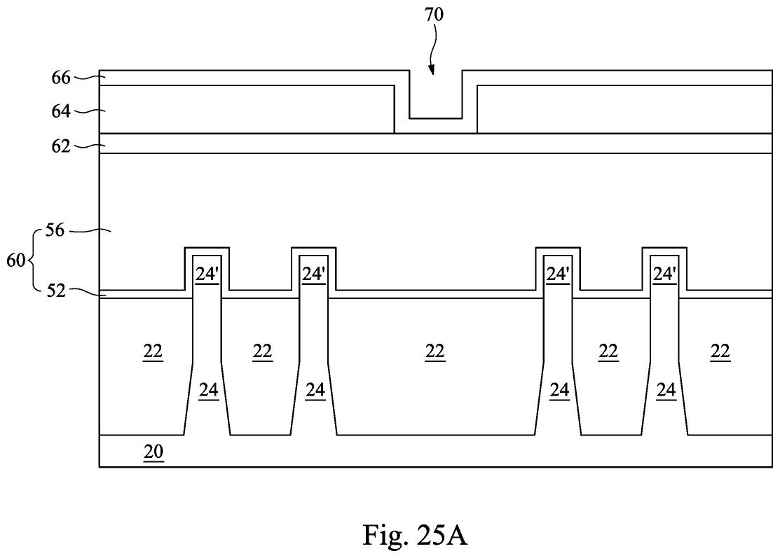

FIGS. 23, 24A, 24B, and 24C illustrate the formation of a hard mask layer 64 and a patterned photoresist 68 with an opening 70, in accordance with some embodiments. A Bottom Anti-Reflective Coating (BARC, not shown) may also be formed between the hard mask layer 64 and the patterned photoresist 68. The hard mask layer 64 may be a single layer or may include multiple layers. For example, the hard mask layer 64 may include one or more layers formed of one or more materials such as silicon nitride, silicon oxynitride, silicon carbonitride, silicon oxycarbonitride, amorphous silicon (a-Si), or the like. For example, in some embodiments, the hard mask layer 64 may comprise a layer of amorphous silicon sandwiched between two layers of silicon nitride, though other combinations of layers or materials are possible. The formation may include ALD, PECVD, or the like.

The photoresist 68 is deposited over the hard mask layer 64. The photoresist 68 may be a single layer structure or a multi-layer (e.g., bi-layer, tri-layer, etc.) structure. The opening 70 is patterned in the photoresist 68 using suitable photolithographic techniques. The opening 70 has a lengthwise direction (viewed from top) perpendicular to the lengthwise direction of the gate stack 60, and a portion of gate stack 60 is directly underlying a portion of opening 70, as illustrated in FIGS. 22, 23, 24A, and 24B. Opening 70 may also extend over some portions of the first ILD 48, as shown in FIGS. 23, 24B, and 24C.

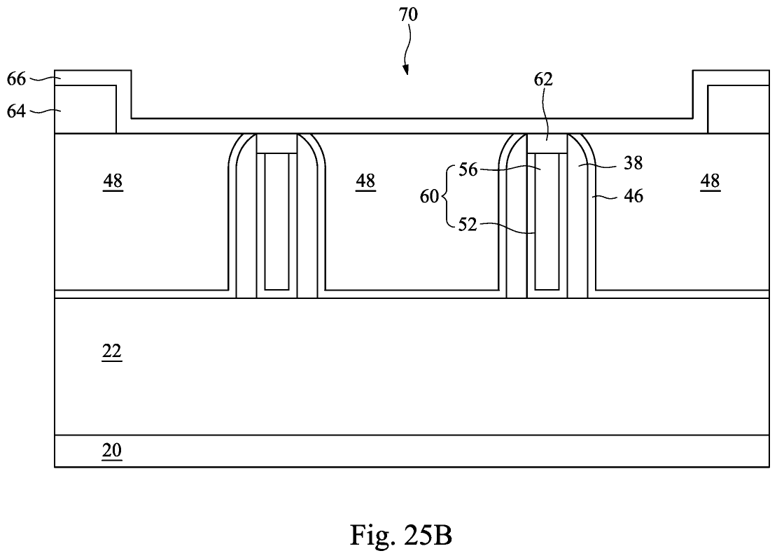

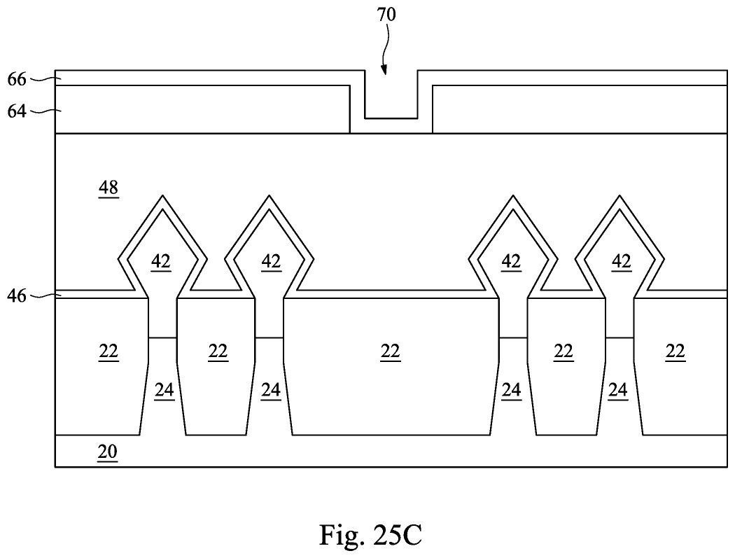

FIGS. 25A, 25B, and 25C illustrate the etching of the hard mask layer 64 and the optional formation of a hard mask layer 66, in accordance with some embodiments. The hard mask layer 64 is etched using the patterned photoresist 68 as an etch mask such that the opening 70 is extended into the hard mask layer 64. Any suitable etch may be used, such as a wet etch, a dry etch, or a combination thereof. The etch may be anisotropic. Multiple etch steps may be used, for example, if the hard mask layer 64 includes multiple layers. The photoresist 68 may be removed using a suitable process, such as using an etching process or ashing process.

After removing the photoresist 68, the hard mask layer 66 may optionally be deposited over the hard mask layer 64 and within the opening 70, in accordance with some embodiments. The hard mask layer 66 may be conformally deposited on top surfaces and sidewall surfaces, and as such may have substantially equal thicknesses on top surfaces and sidewall surfaces. In some embodiments, the hard mask layer 66 comprises a dielectric material such as those described previously for the hard mask layer 64, such as silicon nitride or the like. The hard mask layer 64 and the hard mask layer 66 may be formed of similar or different materials. The hard mask layer 66 may be formed using a suitable process, such as ALD, CVD, or the like. The hard mask layer 66 may be formed to reduce the effective lateral width of the opening 70 and thus reduce the lateral width of the gate isolation region 80 that is subsequently formed in the gate stack 60, described in greater detail below.

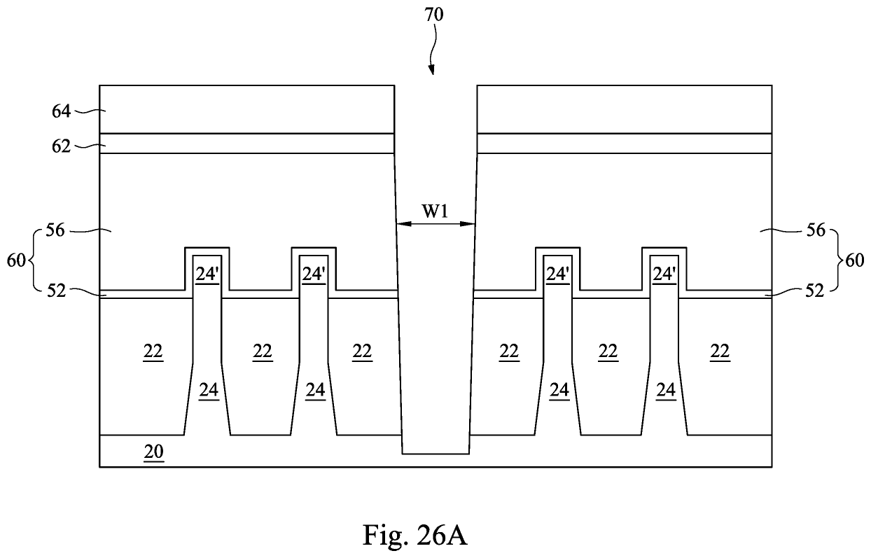

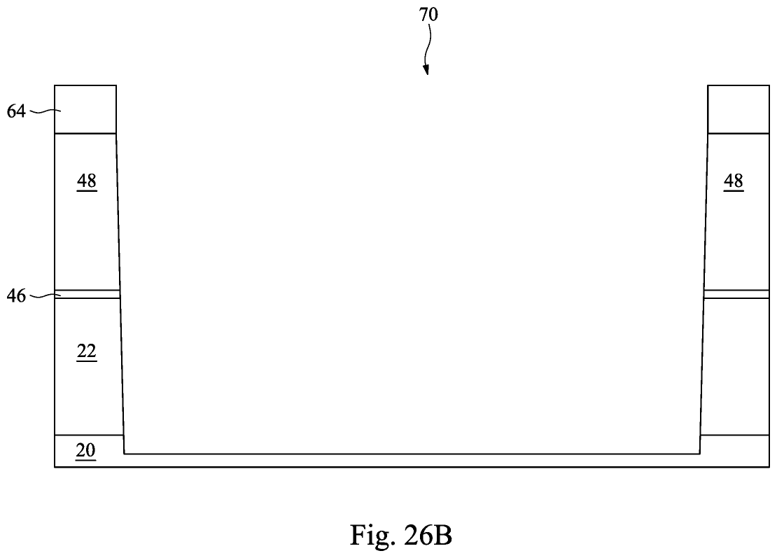

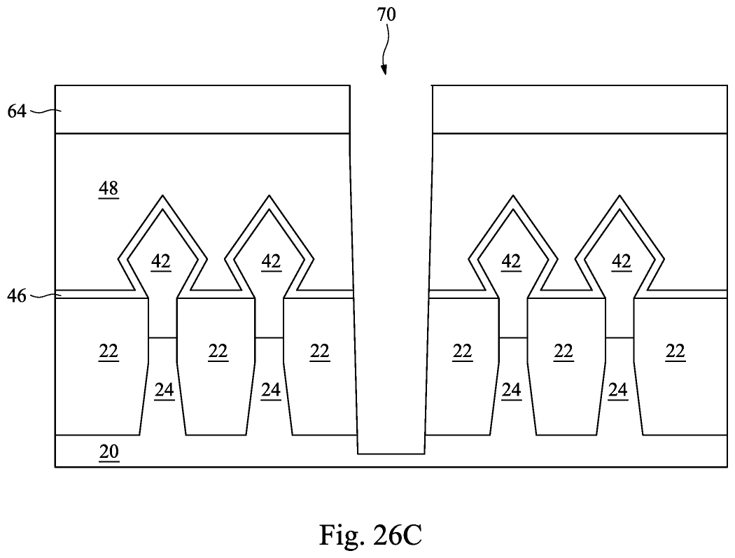

FIGS. 26A, 26B, and 26C illustrate the extending the opening 70 through the gate stack 60 to “cut” the gate stack 60, in accordance with some embodiments. After cutting the gate stack 60, the gate stack 60 will be separated into two separate and electrically isolated gate stacks, each one comprising a portion of the gate stack 60. It should be understood that the gate stack 60 may be separated into multiple portions of the gate stack 60 by additional simultaneous cutting processes.

The opening 70 may be extended through the gate stack 60 by etching the gate stack 60 using the patterned hard mask layer 64 (and the hard mask layer 66, if present) as an etch mask. In some embodiments, the hard mask 62 and gate electrode 56 are etched to extend the opening 70 through the gate electrode 56 and expose the gate dielectric layer 52. Exposed portions of the gate spacers 38 and the exposed portions of the first ILD 48 are also etched. The etching is continued until the now exposed gate dielectric layer 52 is removed, thereby exposing a portion of the isolation regions 22. In some embodiments, the etching may be continued still until at least a portion of the now exposed isolation regions 22 are removed. In some embodiments, the etching may be continued until the isolation regions 22 are removed until a portion of the substrate 20 is exposed. In some embodiments, the etching may be continued further still until a portion of the substrate 20 is removed, as shown in FIGS. 26A-26C. In other embodiments, the bottom of the opening 70 may be disposed in the isolation regions 22 and may not penetrate the substrate 20.

The etching may include multiple cycles using various etchants effective for the removal of the different materials in the gate stack 60. For example, the etching may include one or more wet etching steps and/or dry etching steps. The etching steps may be anisotropic, and may include one or more timed etches. The etching may remove the hard mask layer 66, in some cases. As shown in FIGS. 26A-26C, the opening 70 may extend into (e.g., extend below a top surface of) the substrate 20, in some embodiments. In some embodiments, the opening 70 has a width W1 between the cut gate stacks 60 that is in the range of about 50 nm to about 70 nm, though other widths are possible. The opening 70 may have substantially vertical sidewalls, tapered (e.g., slanted) sidewalls, curved sidewalls, or sidewall surfaces having another profile than these. In this manner, the opening 70 may have different widths between the cut gate stacks 60. The bottom surface of the opening 70 may be substantially flat, convex, or concave.

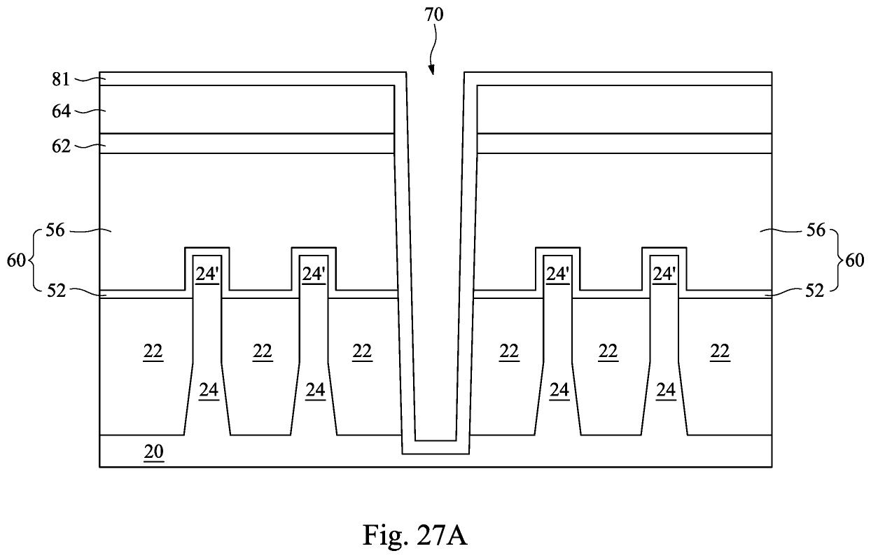

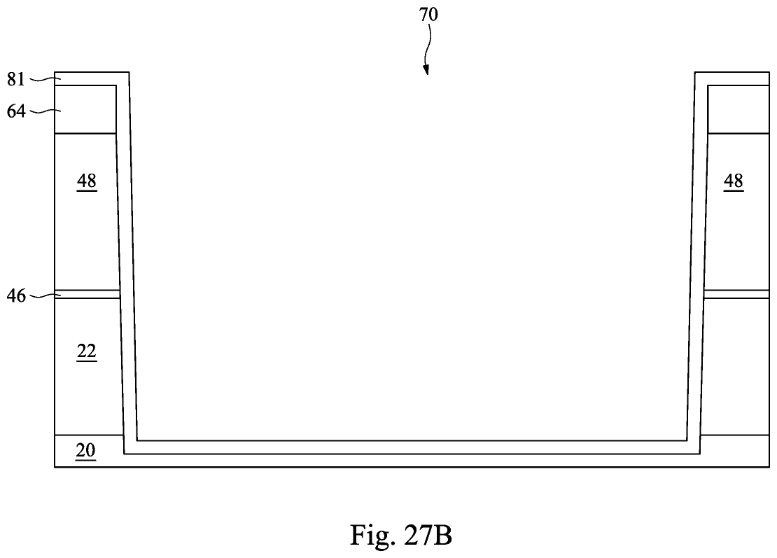

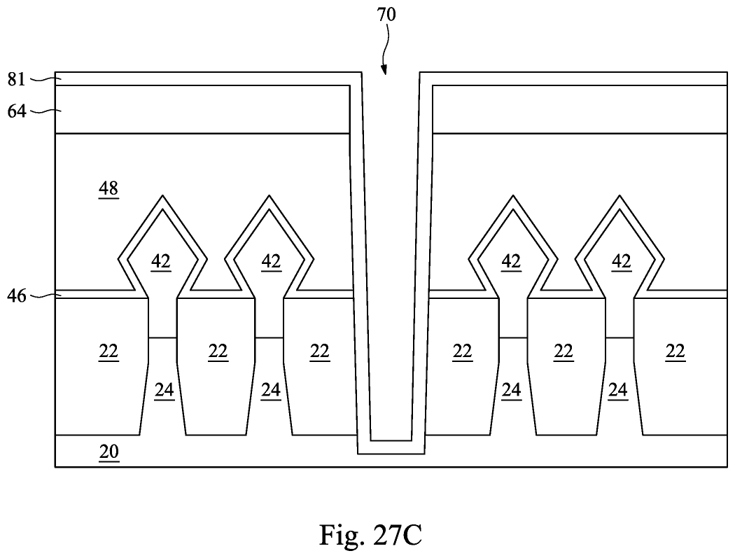

In FIGS. 27A, 27B, and 27C, a stress reduction liner 81 is deposited over the hard mask layer 64 and on surfaces within the opening 70, in accordance with some embodiments. The stress reduction liner 81 is deposited to reduce the stress that the subsequently deposited dielectric fill material 82 exerts on adjacent features, described in greater detail below. In some cases, the stress reduction liner 81 may be considered a “stress relaxation layer” or a “buffer layer.” The stress reduction liner 81 may be deposited on top surfaces and sidewalls of the hard mask layer 64; on sidewalls of the hard mask 62, the gate dielectric layers 52, the gate electrodes 56, the isolation regions 22, the first ILD 48, the CESL 46, and/or the substrate 20; and/or bottom surfaces of the substrate 20. The stress reduction liner 81 may be conformally deposited on surfaces such that the stress reduction liner 81 has a substantially the same thickness on sidewalls and the bottom surface of the opening 70. For example, the stress reduction liner 81 may be deposited using a suitable technique such as ALD, CVD, or the like. In some embodiments, the stress reduction liner 81 may be deposited having a thickness in the range of about 2 nm to about 10 nm, though other thicknesses are possible. In some cases, a thicker stress reduction liner 81 can provide more stress reduction than a thinner stress reduction liner 81. The stress reduction liner 81 may comprise a dielectric material such as silicon oxide, polysilicon, silicon nitride, or the like. For example, in some embodiments, the stress reduction liner 81 may be silicon oxide deposited using ALD, PECVD, or the like. Other materials or deposition techniques are possible. In some embodiments, the stress reduction liner 81 may include more than one layer of material.

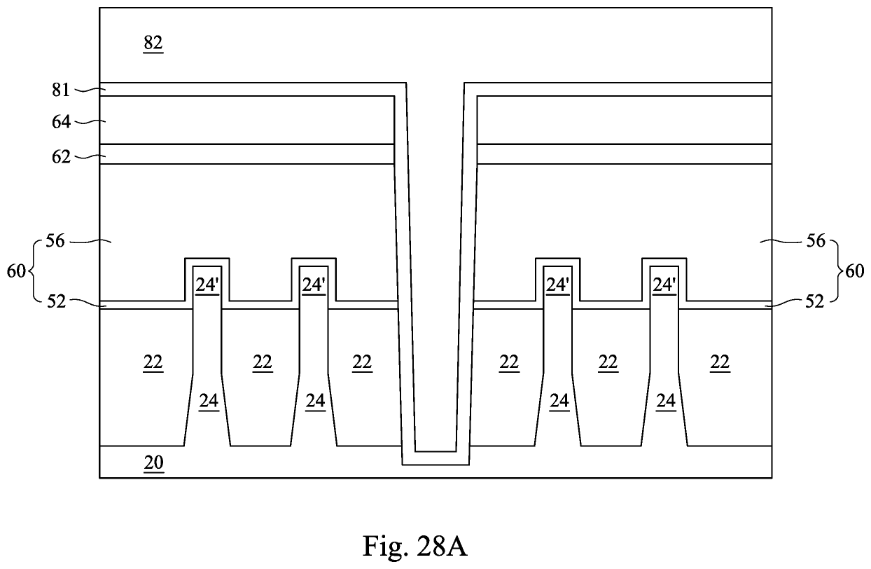

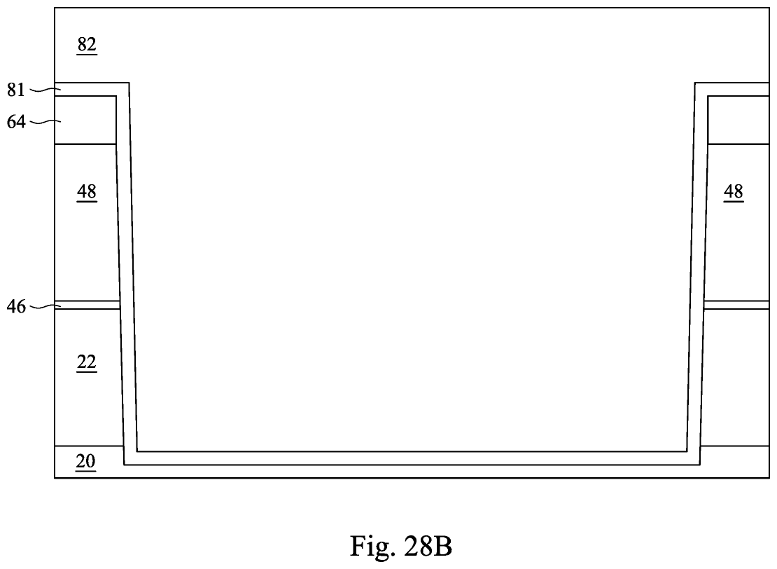

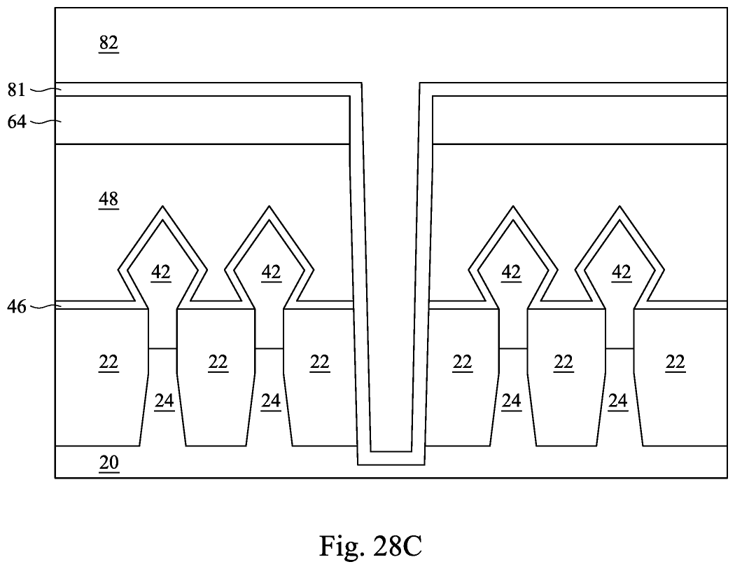

In FIGS. 28A, 28B, and 28C, a dielectric fill material 82 is deposited on the stress reduction liner 81 and within the opening 70, in accordance with some embodiments. The dielectric fill material 82 may partially fill the opening 70, fully fill the opening 70, or overfill the opening 70, as shown in FIGS. 28A-28C. The dielectric fill material 82 may include one or more dielectric materials such as silicon nitride, silicon oxide, silicon carbide, silicon oxynitride, silicon oxycarbide, or the like. The dielectric fill material 82 may be deposited using a suitable technique such as ALD, PECVD, CVD, or the like. For example, in some embodiments, the dielectric fill material 82 is silicon nitride deposited using ALD. Other materials or deposition techniques are possible.

In some cases, stress exerted between the dielectric fill material 82 and adjacent materials can cause undesirable effects. For example, stresses can exist between the dielectric fill material 82 and the adjacent material of the substrate 20, the isolation regions 22, the gate stacks 60, and/or the first ILD 48. In some cases, these stresses can cause lower regions of the dielectric fill material 82 to have a more tapered profile. This tapering can effectively reduce the width of the dielectric fill material 82, which can cause poorer deposition of the dielectric fill material 82 and cause stresses that can negatively impact neighboring FinFETs or other devices. For example, in some cases, the stresses and resulting tapered profile can cause the dielectric fill material 82 to form a seam during deposition, which can result in reduced isolation, reduced structural robustness, or increased chance of leakage. By depositing a stress reduction liner 81 before depositing the dielectric fill material 82, the stresses between the dielectric fill material 82 and adjacent materials can be reduced. For example, the material of the stress reduction liner 81 may be a more flexible material than the dielectric fill material 82 that can absorb some of the stresses. In particular, the stress reduction liner 81 may be used to reduce tapering and unwanted stresses when the opening 70 has a small width (e.g., W1) or a low aspect ratio (e.g. taller shape). In this manner, the presence of the stress reduction liner 81 can reduce tapering, reduce unwanted stress on neighboring devices, and improve the deposition of the dielectric fill material 82, all of which can improve device performance.

In FIGS. 29A, 29B, and 29C, a planarization process is performed to remove excess stress reduction liner 81 and dielectric fill material 82 and form gate isolation region 80, in accordance with some embodiments. The planarization process may include a chemical mechanical polish (CMP) process, a grinding process, an etching process, or the like. After performing the planarization process, top surfaces of the stress reduction liner 81, the dielectric fill material 82, the hard masks 62, and/or the first ILD 48 may be substantially level or coplanar. After performing the planarization process, the remaining portions of the stress reduction liner 81 and the dielectric fill material 82 form gate isolation regions 80 that separate and isolate neighboring gate stacks 60. In some cases, the gate isolation regions 80 described herein may be considered “bi-layer” or “multi-layer” gate isolation structures.

The gate isolation regions 80 may have a height H1 in the range of about 80 nm to about 160 nm. In some embodiments, the gate isolation regions 80 may extend into the substrate 20 a depth in the range of about 15 nm to about 25 nm. The gate isolation regions 80 may have a width W2 between adjacent gate stacks 60 that is in the range of about 15 nm to about 25 nm. The width W2 may be similar to the width W1 of the opening 70 shown in FIG. 26A. In some embodiments, the gate isolation regions 80 have an aspect ratio (e.g., W2:H1) that is in the range of about 1:5 to about 1:20. Other dimensions are possible. In some cases, the use of a stress reduction liner 81 as described herein may allow for the formation of gate isolation regions 80 having lower (e.g., taller) aspect ratios with reduced risk of tapering or other unwanted stress effects. In some embodiments, lower portions of the gate isolation regions 80 may have a sidewall profile with an angle A1 in the range of about 45° to about 90°. Other angles or sidewall profiles are possible. In some cases, the use of a stress reduction liner 81 as described herein may allow for sidewalls of the gate isolation regions 80 to have reduced tapering, which can result in gate isolation regions 80 having more vertical sidewalls or more uniform width.

FIG. 29D illustrates a cross-sectional view of a gate isolation region 80 that is similar to the gate isolation region 80 shown in FIG. 29A, except that the gate isolation region 80 shown in FIG. 29A has a dielectric fill material 82 comprising silicon-rich silicon nitride and a stress reduction liner 81 comprising silicon oxide having a relatively larger thickness. In some embodiments, forming a dielectric fill material 82 of silicon-rich silicon nitride can cause compressive stresses on neighboring FinFET devices that improve performance of those FinFET devices. For example, the FinFET devices may be p-type devices that benefit from compressive channel stress. In some embodiments, the dielectric fill material 82 may be silicon nitride having a concentration of silicon in the range of about 5% to about 30%, though other compositions are possible. To reduce stress, improve deposition, and reduce tapering due to the silicon-rich silicon nitride of the dielectric fill material 82, the stress reduction liner 81 may be deposited to a relatively larger thickness, such as a thickness in the range of about 1.5 nm to about 20 nm. Other thicknesses are possible. In this manner, the stresses due to a gate isolation region 80 may be controlled to reduce undesirable effects and/or improve device performance.

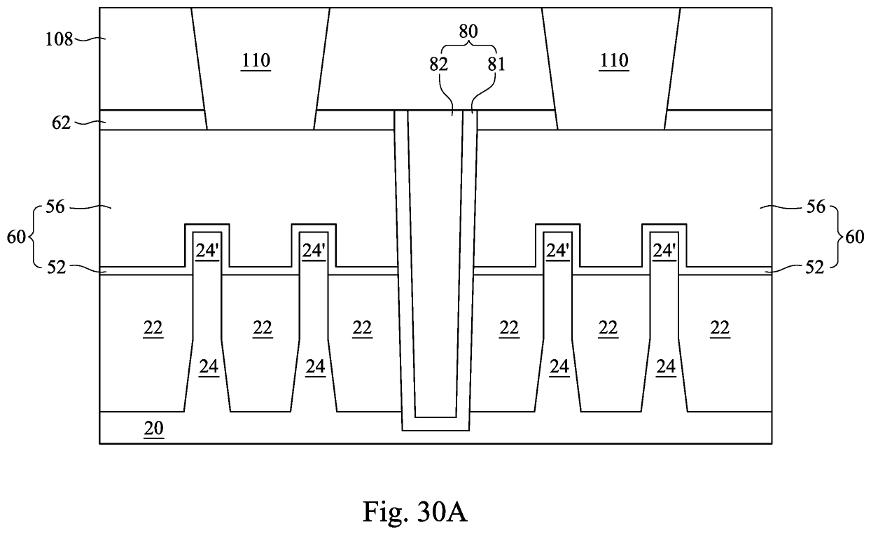

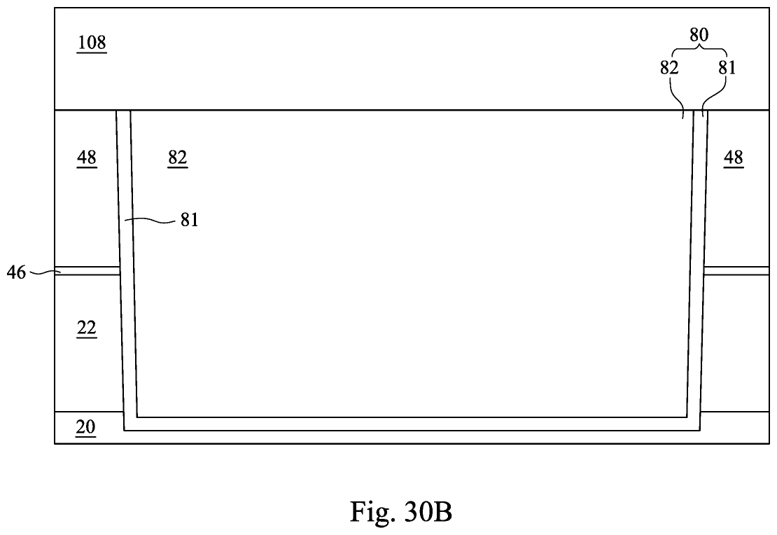

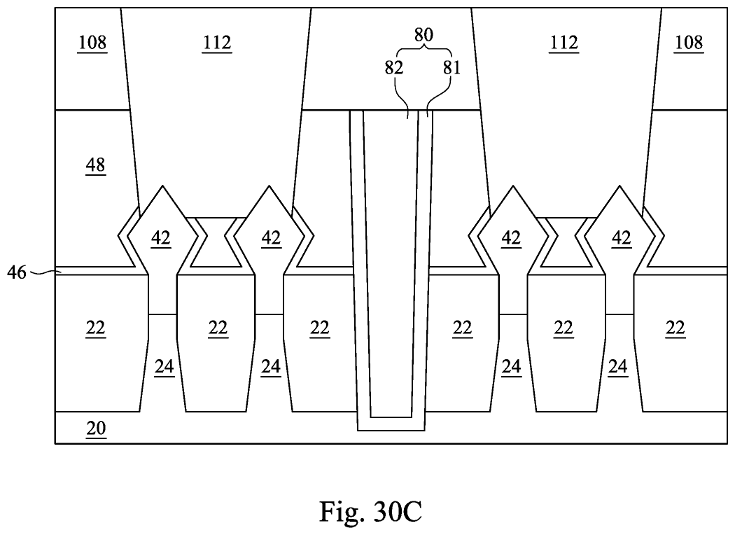

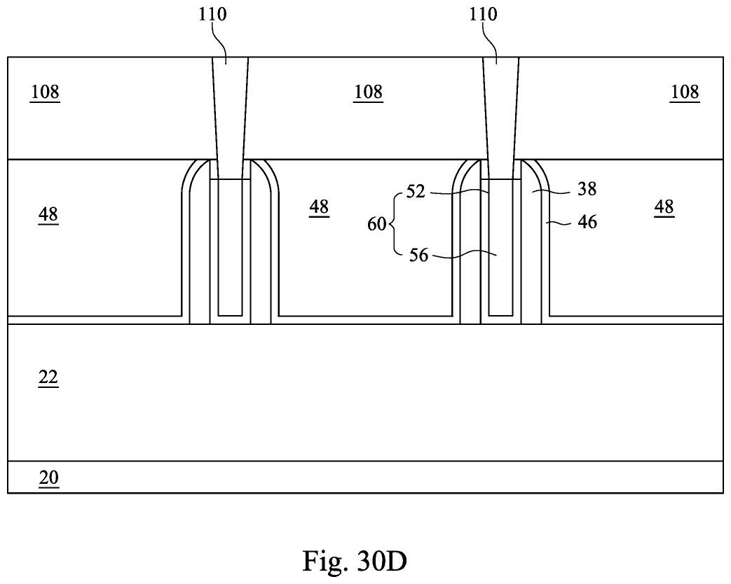

In FIGS. 30A, 30B, 30C, and 30D, a second ILD 108 is deposited over the first ILD 48 and the hard masks 62, in accordance with some embodiments. In some embodiments, the second ILD 108 is a flowable film formed by a flowable CVD method. In other embodiments, the second ILD 108 is formed of a dielectric material such as PSG, BSG, BPSG, USG, or the like, and may be deposited by any suitable method, such as CVD and PECVD. Other materials or deposition techniques are possible.

Also in FIGS. 30A, 30B, 30C, and 30D, gate contacts 110 and source/drain contacts 112 are formed through the second ILD 108 and the first ILD 48, in accordance with some embodiments. Openings for the source/drain contacts 112 are formed through the first ILD 48 and the second ILD 108, and openings for the gate contacts 110 are formed through the second ILD 108 and the hard masks 62. The openings may be formed using acceptable photolithography and etching techniques. A liner, such as a diffusion barrier layer, an adhesion layer, or the like, and a conductive material are formed in the openings. The liner may include titanium, titanium nitride, tantalum, tantalum nitride, or the like. The conductive material may be copper, a copper alloy, silver, gold, tungsten, cobalt, aluminum, nickel, ruthenium, or the like. A planarization process, such as a CMP, may be performed to remove excess material from a surface of the second ILD 108. The remaining liner and conductive material form the source/drain contacts 112 and gate contacts 110 in the openings. An anneal process may be performed to form a silicide (not separately illustrated in the figures) at the interface between the epitaxial source/drain regions 42 and the source/drain contacts 112.

The source/drain contacts 112 are physically and electrically coupled to epitaxial source/drain regions 42, and the gate contacts 110 are physically and electrically coupled to gate electrodes 56 of gate stacks 60. However, gate contacts 110 coupled to one cut portion of the gate stacks 60 may be electrically isolated from the gate contacts 110 coupled to another cut portion of the gate stacks 60 by a gate isolation region 80. The source/drain contacts 112 and gate contacts 110 may be formed in different processes or may be formed in the same process. The source/drain contacts 112 and gate contacts 110 may be formed in a same cross-section or in different cross-sections.

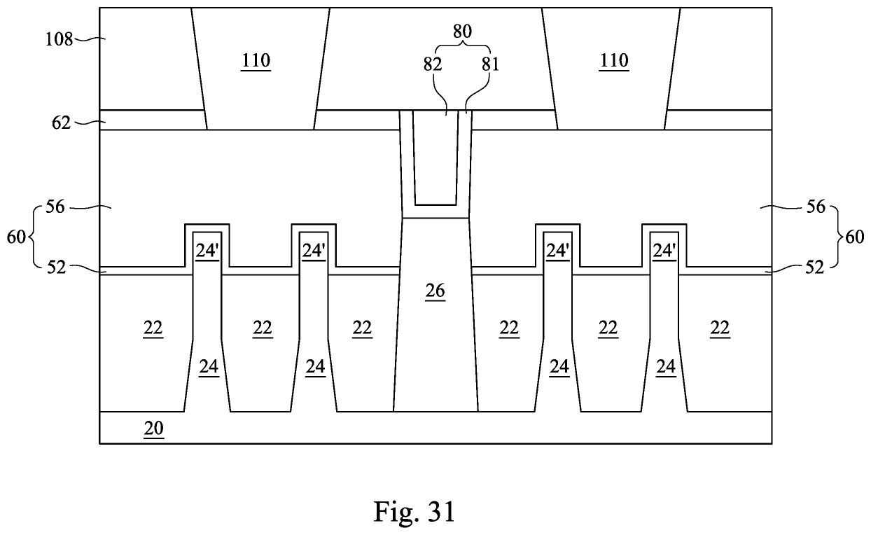

The gate isolation regions 80 described herein may be used in addition to other isolation structures, in some embodiments. As an example, FIG. 31 illustrates a cross-sectional view of a structure similar to that of FIG. 30A, except that a dielectric fin 26 (e.g., a “hybrid fin” or “dummy fin”) has been formed between neighboring fins 24 and neighboring gate stacks 60. In accordance with some embodiments, the dielectric fin 26 may be formed by etching one of the fins 24 to form a recess, and then filling the recess with a dielectric material. As shown in FIG. 31, the dielectric fin 26 may be formed on the substrate 20 and may protrude above the isolation regions 22. The dielectric fin 26 may have a height that is less than, about the same as, or greater than a height of the fins 24. The gate isolation region 80 may be formed in a manner similar to the gate isolation region 80 of FIG. 30A. For example an opening may be etched in the gate stacks 60 similar to opening 70, except that the opening may expose a top surface of the dielectric fin 26. The stress reduction liner 81 and the dielectric fill material 82 may then be deposited into the opening. In some embodiments, some portions of a gate isolation region 80 may be formed on a dielectric fin 26 and other portions of the same gate isolation region 80 may be formed away from the dielectric fin 26. Thus, in some embodiments, a gate isolation region 80 may have portions with different heights, widths, and/or aspect ratios. By forming a gate isolation region 80 having a stress reduction liner 81, stresses at the edge of the gate stacks 60 may be reduced, and the location or size of the isolating features of the gate stack 60 may be more precisely controlled.

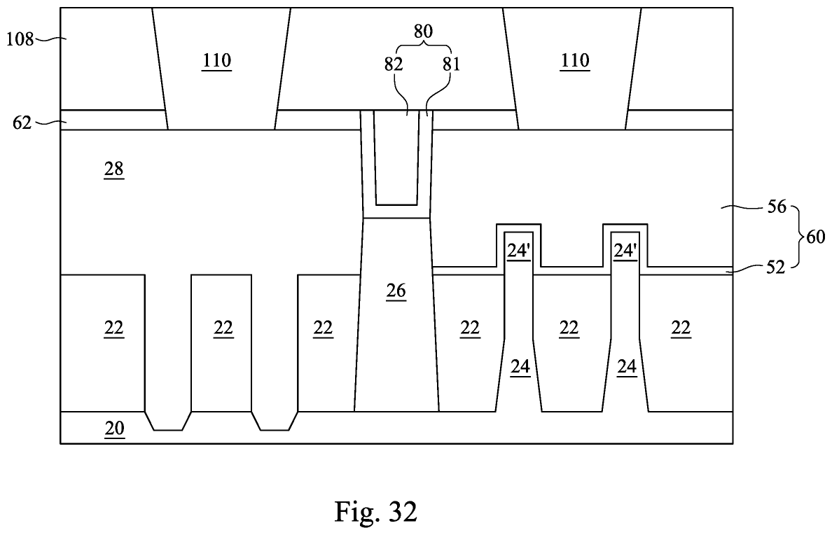

As another example, FIG. 32 illustrates a cross-sectional view of a structure similar to that of FIG. 31, except a fin isolation region 28 has been formed in addition to the dielectric fin 26 and the gate isolation region 80. The fin isolation region 28 may be formed after formation of the gate stacks 60 but before formation of the gate isolation regions 80, in some embodiments. The fin isolation region 28 may be formed, for example, by removing a portion of the gate stacks 60 and removing the underlying fins 24 to form an opening, and then depositing a dielectric material in the opening. After forming the fin isolation region 28, the gate isolation region 80 may be formed using etching and deposition techniques described previously. By forming a gate isolation region 80 having a stress reduction liner 81, stresses at the edge of the gate stacks 60 may be reduced, and the location or size of the isolating features of the gate stack 60 may be more precisely controlled.

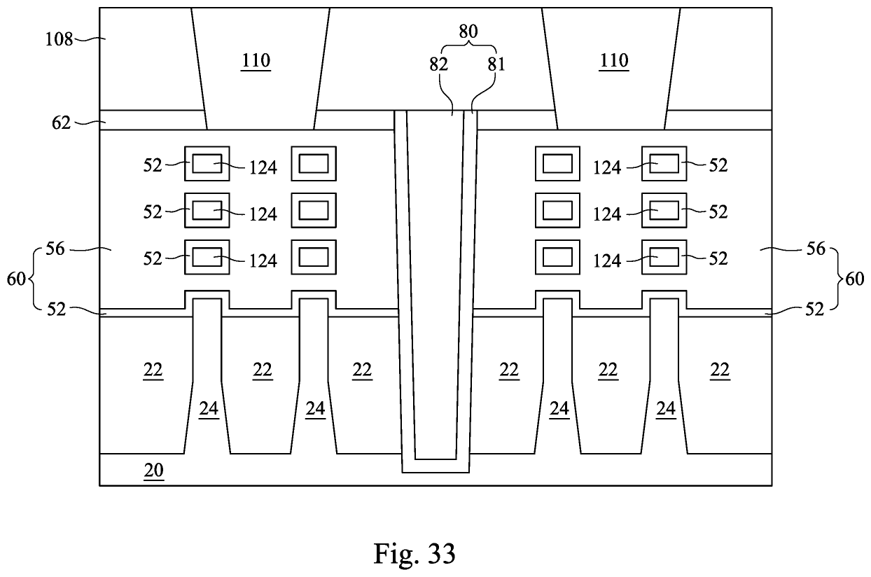

FIG. 33 illustrates a cross-sectional view of a structure comprising nano-structure transistors (e.g., nano-FETs, nanosheet FETs, nanowire FETs, Gate-All-Around (GAA) transistors, or the like) separated by a gate isolation region 80, in accordance with some embodiments. The cross-section of FIG. 33 is similar to the cross-section of FIG. 31. The nano-structure transistors comprise nanostructures 124 (e.g., nanosheets, nanowire, or the like) over fins 24, wherein the nanostructures 124 act as channel regions for the nano-structure transistors. The nanostructures 124 may include p-type nanostructures, n-type nanostructures, or a combination thereof. Gate dielectric layers 52 are over top surfaces of the fins 24 and along top surfaces, sidewalls, and bottom surfaces of the nanostructures 124. Gate electrodes 60 are over the gate dielectric layers 52, and the gate dielectric layers 52 and gate electrodes 60 together comprise replacement gates 60. Neighboring replacement gates 60 are separated by a gate isolation region 80, which may be formed using etching and deposition techniques described previously. Epitaxial source/drain regions (not shown in FIG. 33) are disposed on opposing sides of the nanostructures 124.

Embodiment processes and devices advantageously use a stress-reducing liner in the gate isolation region between two cut ends of a replacement gate (e.g., metal gate) of adjacent FinFET devices. The use of a stress-reducing liner can reduce tapering or bending of the sidewalls of the gate isolation region. This can reduce the chance of seams or voids being formed in a dielectric material of the gate isolation region. This can also reduce undesirable stresses that may affect the performance of neighboring devices. Embodiments are described in the context of a cut metal gate, but a stress-reducing liner as described herein may be used in any suitable feature in which a material such as silicon nitride is deposited to fill a trench or opening. In this manner, isolation features may be formed having smaller widths, more uniform widths, and having higher yield.

In an embodiment of the present disclosure, a method includes etching a gate stack to form a trench extending through the gate stack, the gate stack including a metal gate electrode and a gate dielectric, wherein forming the trench removes a portion of the gate stack to separate the gate stack into a first gate stack portion and a second gate stack portion; extending the trench through an isolation region under the gate stack and into a semiconductor substrate under the isolation region; conformally depositing a first dielectric material on surfaces in the trench; and depositing a second dielectric material on the first dielectric material to fill the trench, wherein the first dielectric material is a more flexible material than the second dielectric material. In an embodiment, the first dielectric material is silicon oxide. In an embodiment, the second dielectric material is silicon nitride. In an embodiment, the second dielectric material is deposited using an Atomic Layer Deposition (ALD) process. In an embodiment, the method includes forming a hard mask on the gate stack, wherein the first dielectric material physically contacts a sidewall of the hard mask. In an embodiment, the trench extends a depth into the semiconductor substrate that is in the range of 0 nm to 25 nm. In an embodiment, the second dielectric material is free of seams. In an embodiment, the first dielectric material has a thickness in the range of 2 nm to 10 nm.

In an embodiment of the present disclosure, a method includes forming a first fin and a second fin over a substrate; forming an isolation region surrounding the first fin and surrounding the second fin; forming a gate structure extending over the first fin and the second fin; forming an opening extending through the gate structure and the isolation region to expose the substrate, wherein the opening is between the first fin and the second fin; depositing a conformal layer of a first dielectric material in the opening, wherein the first dielectric material in the opening physically contacts the gate structure, the isolation region, and the substrate; and depositing a second dielectric material on the first dielectric material in the opening, wherein the first dielectric material reduces stresses exerted between the second dielectric material and the substrate. In an embodiment, the first dielectric material includes silicon oxide. In an embodiment, the second dielectric material includes silicon nitride. In an embodiment, the second dielectric material has a silicon concentration in the range of 5% to 30%. In an embodiment, the opening near the substrate has the same sidewall profile before and after depositing the second dielectric material. In an embodiment, the first dielectric material is deposited using ALD or PECVD. In an embodiment, the method includes forming a hard mask on the gate structure, wherein top surfaces of the hard mask, the first dielectric material, and the second dielectric material are level.

In an embodiment of the present disclosure, a device includes a first semiconductor fin over a substrate; a second semiconductor fin over the substrate; an isolation region surrounding the first semiconductor fin and the second semiconductor fin; a first gate stack over the first semiconductor fin; a second gate stack over the second semiconductor fin; and a gate isolation region separating the first gate stack from the second gate stack, wherein the gate isolation region includes: a layer of silicon oxide that physically contacts the first gate stack and the second gate stack; and a dielectric fill material on the layer of silicon oxide. In an embodiment, the dielectric fill material is silicon nitride. In an embodiment, the layer of silicon oxide physically contacts the substrate. In an embodiment, the device includes a dielectric fin between the first semiconductor fin and the second semiconductor fin, wherein the layer of silicon oxide physically contacts a top surface of the dielectric fin. In an embodiment, the dielectric fill material provides compressive stress to the first semiconductor fin and the second semiconductor fin.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
etching a gate stack to form a trench extending through the gate stack, the gate stack comprising a metal gate electrode and a gate dielectric, wherein forming the trench removes a portion of the gate stack to separate the gate stack into a first gate stack portion and a second gate stack portion;
extending the trench through an isolation region under the gate stack and into a semiconductor substrate under the isolation region;
conformally depositing a first dielectric material on surfaces in the trench; and
depositing a second dielectric material on the first dielectric material to fill the trench, wherein the first dielectric material is a more flexible material than the second dielectric material.

2. The method of claim 1, wherein the first dielectric material is silicon oxide.

3. The method of claim 1, wherein the second dielectric material is silicon nitride.

4. The method of claim 1, wherein the second dielectric material is deposited using an Atomic Layer Deposition (ALD) process.

5. The method of claim 1, further comprising forming a hard mask on the gate stack, wherein the first dielectric material physically contacts a sidewall of the hard mask.

6. The method of claim 1, wherein the trench extends a depth into the semiconductor substrate that is in the range of 0 nm to 25 nm.

7. The method of claim 1, wherein the second dielectric material is free of seams.

8. The method of claim 1, wherein the first dielectric material has a thickness in the range of 2 nm to 10 nm.

9. A method comprising:
forming a first fin and a second fin over a substrate;
forming an isolation region surrounding the first fin and surrounding the second fin;
forming a gate structure extending over the first fin and the second fin;
forming an opening extending through the gate structure and the isolation region to expose the substrate, wherein the opening is between the first fin and the second fin;
depositing a conformal layer of a first dielectric material in the opening, wherein the first dielectric material in the opening physically contacts the gate structure, the isolation region, and the substrate; and
depositing a second dielectric material on the first dielectric material in the opening, wherein the first dielectric material reduces stresses exerted between the second dielectric material and the substrate.

10. The method of claim 9, wherein the first dielectric material comprises silicon oxide.

11. The method of claim 9, wherein the second dielectric material comprises silicon nitride.

12. The method of claim 11, wherein the second dielectric material has a silicon concentration in the range of 5% to 30%.

13. The method of claim 9, wherein the opening near the substrate has the same sidewall profile before and after depositing the second dielectric material.

14. The method of claim 9, wherein the first dielectric material is deposited using ALD or PECVD.

15. The method of claim 9 further comprising forming a hard mask on the gate structure, wherein top surfaces of the hard mask, the first dielectric material, and the second dielectric material are level.

16. A device comprising:
a first semiconductor fin over a substrate;
a second semiconductor fin over the substrate;
an isolation region surrounding the first semiconductor fin and the second semiconductor fin;
a first gate stack over the first semiconductor fin;
a second gate stack over the second semiconductor fin; and
a gate isolation region separating the first gate stack from the second gate stack, wherein the gate isolation region comprises:
a layer of silicon oxide that physically contacts the first gate stack and the second gate stack; and
a dielectric fill material on the layer of silicon oxide.

17. The device of claim 16, wherein the dielectric fill material is silicon nitride.

18. The device of claim 16, wherein the layer of silicon oxide physically contacts the substrate.

19. The device of claim 16 further comprising a dielectric fin between the first semiconductor fin and the second semiconductor fin, wherein the layer of silicon oxide physically contacts a top surface of the dielectric fin.

20. The device of claim 16, wherein the dielectric fill material provides compressive stress to the first semiconductor fin and the second semiconductor fin.
